(19) United States
(12) Patent Application Publication
(10) Pub. No.: US 2025/0311505 A1
(43) Pub. Date: Oct. 2, 2025

(54) DISPLAY APPARATUS, METHOD OF MANUFACTURING THE SAME, AND ELECTRONIC APPARATUS INCLUDING THE SAME

(71) Applicant: Samsung Display Co., Ltd., Yongin-si (KR)

(72) Inventors: Hyunwoo Noh, Yongin-si (KR); Junghyun Kwon, Yongin-si (KR); Youngmin Kim, Yongin-si (KR); Moonjung Baek, Yongin-si (KR); Daeho Lee, Yongin-si (KR)

(21) Appl. No.: 19/026,088

(22) Filed: Jan. 16, 2025

(30) Foreign Application Priority Data
Mar. 29, 2024 (KR) 10-2024-0043623

(51) Int. Cl. H10H 29/80; H10H 29/24; H10H 29/37

(52) U.S. Cl. CPC H10H 29/8321; H10H 29/24; H10H 29/37

(57) ABSTRACT

A display apparatus includes: a pixel-defining layer on first and second pixel electrodes, the pixel defining layer including first and second openings exposing a portion of the first and second pixel electrodes, respectively, and having a reverse taper shape; first and second intermediate layers respectively in the first and second openings; first and second opposite electrodes respectively on the first and second intermediate layers; a first dummy pattern and a second dummy pattern each on an upper surface of the pixel-defining layer; a first auxiliary electrode pattern covering the first opposite electrode, a lateral surface of the pixel-defining layer, and the first dummy pattern; a second auxiliary electrode pattern covering the second opposite electrode, a lateral surface of the pixel-defining layer, and the second dummy pattern; and an auxiliary electrode layer on the first auxiliary electrode pattern, the second auxiliary electrode pattern, and the pixel-defining layer.

### CROSS-REFERENCE TO RELATED APPLICATION

The present application claims priority to and the benefit of Korean Patent Application No. 10-2024-0043623, filed on Mar. 29, 2024, in the Korean Intellectual Property Office, the entire content of which is incorporated herein by reference.

### BACKGROUND

### 1. Field

One or more embodiments of the present disclosure relate to a display apparatus and a method of manufacturing the display apparatus.

### 2. Description of the Related Art

Recently, the usage of display apparatuses has diversified (broadened). Concurrently, as display apparatuses have become thinner and more lightweight, their range of use has gradually been extended. That is, the evolution towards slimmer and lighter display apparatus designs has expanded in their applicability.

Generally, a display apparatus includes a plurality of pixels that receive electrical signals and emit light to display images. A pixel of the display apparatus may include a light-emitting diode as a display element, and the light-emitting diode may include a pixel electrode, an emission layer, and an opposite electrode.

### SUMMARY

Aspects of embodiments of the present disclosure are directed toward a display apparatus with reduced manufacturing costs and/or reduced manufacturing time, and a method of manufacturing the display apparatus.

Additional aspects will be set forth in part in the description which follows and, in part, will be apparent from the description, or may be learned by practice of the presented embodiments of the disclosure.

According to one or more embodiments of the present disclosure, a display apparatus includes: a first pixel electrode and a second pixel electrode arranged apart (e.g., spaced and/or apart) from each other; a pixel-defining layer on the first pixel electrode and the second pixel electrode, having a first opening exposing a portion of the first pixel electrode and a second opening exposing a portion of the second pixel electrode, and having a reverse taper shape in a cross-sectional view, a first intermediate layer and a second intermediate layer in the first opening and the second opening of the pixel-defining layer, respectively; a first opposite electrode on the first intermediate layer in the first opening of the pixel-defining layer and a second opposite electrode on the second intermediate layer in the second opening of the pixel-defining layer; a first dummy pattern and a second dummy pattern each on an upper surface of the pixel-defining layer, wherein the first dummy pattern includes (substantially) the same material as the first intermediate layer, and the second dummy pattern includes (substantially) the same material as the second intermediate layer; a first auxiliary electrode pattern covering an upper surface of the first opposite electrode, a lateral surface of the pixel-defining layer that defines the first opening, and an upper surface of the first dummy pattern; a second auxiliary electrode pattern covering an upper surface of the second opposite electrode, a lateral surface of the pixel-defining layer that defines the second opening, and an upper surface of the second dummy pattern; and an auxiliary electrode layer on the first auxiliary electrode pattern, the second auxiliary electrode pattern, and the pixel-defining layer.

In one or more embodiments, the auxiliary electrode layer may entirely overlap (e.g., may overlap an entirety of each of) the first auxiliary electrode pattern, the second auxiliary electrode pattern, and the pixel-defining layer.

In one or more embodiments, a thickness of the first auxiliary electrode pattern may be greater than a thickness of the first opposite electrode.

In one or more embodiments, the first auxiliary electrode pattern may be apart from the second auxiliary electrode pattern.

In one or more embodiments, each of the first auxiliary electrode pattern and the second auxiliary electrode pattern may have an island pattern shape in a plan view.

In one or more embodiments, the first auxiliary electrode pattern may cover an inner surface of the first dummy pattern, and the second auxiliary electrode pattern may cover an inner surface of the second dummy pattern.

In one or more embodiments, the auxiliary electrode layer may cover an outer surface of the first dummy pattern and an outer surface of the second dummy pattern.

In one or more embodiments, the first dummy pattern may be apart (e.g., spaced and/or apart) from the second dummy pattern.

In one or more embodiments, the first dummy pattern may include a first dummy intermediate layer including (substantially) the same material as the first intermediate layer, and a first dummy opposite electrode including (substantially) the same material as the first opposite electrode, and the second dummy pattern may include a second dummy intermediate layer including (substantially) the same material as the second intermediate layer, and a second dummy opposite electrode including (substantially) the same material as the second opposite electrode.

In one or more embodiments, each of the first auxiliary electrode pattern and the second auxiliary electrode pattern may include a light-transmissive conductive material.

In one or more embodiments, the pixel-defining layer may include a negative type or kind photosensitive organic material.

According to one or more embodiments of the present disclosure, a display apparatus includes: a first pixel electrode and a second pixel electrode arranged apart from each other; a pixel-defining layer on the first pixel electrode and the second pixel electrode, having a first opening exposing a portion of the first pixel electrode and a second opening exposing a portion of the second pixel electrode, and having a reverse taper shape in a cross-sectional view; a first intermediate layer and a second intermediate layer in the first opening and the second opening of the pixel-defining layer, respectively; an opposite electrode covering the first intermediate layer, the second intermediate layer, an upper surface of the pixel-defining layer, at least a portion of a lateral surface of the pixel-defining layer that defines the first opening, and at least a portion of a lateral surface of the pixel-defining layer that defines the second opening; and a first dummy pattern and a second dummy pattern each on an upper surface of the pixel-defining layer, wherein the first dummy pattern includes (substantially) the same material as the first intermediate layer, and the second dummy pattern includes (substantially) the same material as the second intermediate layer.

In one or more embodiments, the opposite electrode may entirely overlap (e.g., may overlap an entirety of) an upper surface of the pixel-defining layer.

In one or more embodiments, the first dummy pattern may be apart from the second dummy pattern.

In one or more embodiments, the opposite electrode may be in contact with the first dummy pattern and the second dummy pattern.

In one or more embodiments, the pixel-defining layer may include a negative type or kind photosensitive organic material.

According to one or more embodiments of the present disclosure, an electronic apparatus includes: a first pixel electrode and a second pixel electrode arranged apart from each other; a pixel-defining layer on the first pixel electrode and the second pixel electrode, having a first opening exposing a portion of the first pixel electrode and a second opening exposing a portion of the second pixel electrode, and having an reverse taper shape in a cross-sectional view; a first intermediate layer and a second intermediate layer in the first opening and the second opening of the pixel-defining layer, respectively; a first opposite electrode on the first intermediate layer in the first opening of the pixel-defining layer and a second opposite electrode on the second intermediate layer in the second opening of the pixel-defining layer; and a first dummy pattern and a second dummy pattern each on an upper surface of the pixel-defining layer, wherein the first dummy pattern includes (substantially) the same material as the first intermediate layer, and the second dummy pattern includes (substantially) the same material as the second intermediate layer, wherein the first dummy pattern is apart from the second dummy pattern, and the first opposite electrode is electrically connected to the second opposite electrode.

In one or more embodiments, the electronic apparatus may further include a first auxiliary electrode pattern covering an upper surface of the first opposite electrode, a lateral surface of the pixel-defining layer that defines the first opening, and an upper surface of the first dummy pattern, a second auxiliary electrode pattern covering an upper surface of the second opposite electrode, a lateral surface of the pixel-defining layer that defines the second opening, and an upper surface of the second dummy pattern, and an auxiliary electrode layer on the first auxiliary electrode pattern and the second auxiliary electrode pattern, wherein the auxiliary electrode layer may electrically connect the first auxiliary electrode pattern to the second auxiliary electrode pattern.

In one or more embodiments, the first opposite electrode and the second opposite electrode may be integrally provided to overlap an entire upper surface of the pixel-defining layer.

In one or more embodiments, the pixel-defining layer may include a negative type or kind photosensitive organic material.

According to one or more embodiments of the present disclosure, a method of manufacturing a display apparatus includes: forming a pixel electrode; forming, on the pixel electrode, a pixel-defining layer including an opening that exposes a portion of the pixel electrode and having a reverse taper shape; forming, in the opening of the pixel-defining layer, an intermediate layer overlapping the pixel electrode, and forming a preliminary dummy intermediate layer on an upper surface of the pixel-defining layer; forming, in the opening of the pixel-defining layer, an opposite electrode arranged on the intermediate layer, and forming a preliminary dummy opposite electrode on the preliminary dummy intermediate layer; forming a preliminary auxiliary electrode pattern to cover an upper surface of the opposite electrode, a lateral surface of the pixel-defining layer that defines the opening, and an upper surface of the preliminary dummy opposite electrode; forming a dummy pattern including a dummy intermediate layer and a dummy opposite electrode on an upper surface of the pixel-defining layer by removing a portion of the preliminary dummy intermediate layer and the preliminary dummy opposite electrode; and forming an auxiliary electrode pattern covering an upper surface of the opposite electrode, a lateral surface of the pixel-defining layer, and an upper surface of the dummy pattern by removing a portion of the preliminary auxiliary electrode pattern, and forming an auxiliary electrode layer on the auxiliary electrode pattern and the pixel-defining layer.

In one or more embodiments, the forming of the pixel-defining layer having the reverse taper shape may include stacking a preliminary pixel-defining layer including a photosensitive organic material, and forming the pixel-defining layer having the opening by performing exposing and developing processes on the preliminary pixel-defining layer and removing a portion of the preliminary pixel-defining layer that overlaps the pixel electrode.

According to one or more embodiments of the present disclosure, a method of manufacturing a display apparatus includes: forming a pixel electrode; forming, on the pixel electrode, a pixel-defining layer including an opening that exposes a portion of the pixel electrode and having a reverse taper shape; forming, in the opening of the pixel-defining layer, an intermediate layer overlapping the pixel electrode, and a preliminary dummy intermediate layer on an upper surface of the pixel-defining layer; forming a sacrificial layer to cover an upper surface of the intermediate layer, a lateral surface of the pixel-defining layer that defines the opening, and an upper surface of the preliminary dummy intermediate layer;

forming a dummy intermediate layer on an upper surface of the pixel-defining layer by removing a portion of the preliminary dummy intermediate layer; and forming a sacrificial pattern covering an upper surface of the opposite electrode, the lateral surface of the pixel-defining layer, and an upper surface of the dummy intermediate layer by removing a portion of the sacrificial layer; removing the sacrificial layer; and forming an opposite electrode covering the intermediate layer, the lateral surface and upper surface of the pixel-defining layer, and the dummy intermediate layer.

In one or more embodiments, the sacrificial layer may include an inorganic layer or a conductive layer.

In one or more embodiments, the electronic apparatus may further include: a display module; a processor; a power module; and a memory, wherein the display apparatus may include one of the display module, the processor, the power module, or the memory.

### BRIEF DESCRIPTION OF THE DRAWINGS

The above and other aspects, features, and/or principles of certain embodiments of the present disclosure will be more apparent from the following description taken in conjunction with the accompanying drawings, in which:

FIGS. 1A and 1B are each a schematic perspective view of a display apparatus according to one or more embodiments of the present disclosure;

FIGS. 2A and 2B are each a schematic equivalent circuit diagram of a light-emitting element corresponding to one of pixels of the display apparatus and a pixel circuit electrically connected to a relevant light-emitting element according to one or more embodiments of the present disclosure;

FIG. 3 is a schematic cross-sectional view of a portion of a display apparatus according to one or more embodiments of the present disclosure;

FIG. 4 is a cross-sectional view of a stack structure of a first light-emitting element of the display apparatus of FIG. 3, according to one or more embodiments of the present disclosure;

FIG. 5 is a schematic cross-sectional view of a portion of a display apparatus according to one or more embodiments of the present disclosure;

FIG. 6 is a schematic cross-sectional view of a display apparatus according to one or more embodiments of the present disclosure;

FIGS. 7A-7C are schematic cross-sectional views showing states corresponding to a process of manufacturing a display apparatus according to one or more embodiments of the present disclosure;

FIGS. 8A-8H are schematic cross-sectional views showing states corresponding to a process of manufacturing a display apparatus according to one or more embodiments of the present disclosure; and

FIGS. 9A-9H are schematic cross-sectional views showing states corresponding to a process of manufacturing a display apparatus according to one or more embodiments of the present disclosure.

FIG. 10 is a block diagram of an electronic apparatus according to an embodiment.

FIG. 11 is a schematic diagrams of electronic apparatuses according to various embodiments.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, duplicative descriptions thereof may not be provided.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the present disclosure, and methods for achieving them will be clarified with reference to one or more embodiments described below in more detail with reference to the drawings. However, the disclosure is not limited to the following embodiments and may be embodied in one or more suitable forms.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The singular forms “a,” “an,” and “the” as used herein are intended to include the plural forms as well, unless the context clearly indicates otherwise.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

It will be understood that when an element, such as an area, layer, film, region or portion, is referred to as being “on” or “connected to” another element, it can be directly on or connected to the other element, or one or more intervening elements may be present. In addition, it will also be understood that when an element is referred to as being “between” two elements, it can be the only element between the two elements, or one or more intervening elements may also be present.

Sizes of elements in the drawings may be exaggerated or reduced for convenience of explanation. As an example, the size and thickness of each element shown in the drawings may be arbitrarily represented for convenience of description, and thus, the disclosure is not necessarily limited thereto.

In the case where a certain embodiment may be implemented differently, a specific process order may be performed in the order different from the described order. As an example, two processes successively described may be concurrently (e.g., simultaneously) performed substantially and performed in the opposite order.

It will be understood that if (e.g., when) a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that if (e.g., when) a layer, region, or element is referred to as being “electrically connected” to another layer, region, or element, it may be “directly electrically connected” to the other layer, region, or element or may be “indirectly electrically connected” to the other layer, region, or element with another layer, region, or element arranged therebetween.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the terms “use,” “using,” and “used” may be considered synonymous with the terms “utilize,” “utilizing,” and “utilized,” respectively.

The x-axis, the y-axis and the z-axis are not limited to three axes of the rectangular coordinate system, and may be interpreted in a broader sense. For example, the x-axis, the y-axis, and the z-axis may be normal (e.g., perpendicular) to one another, or may represent different orientations that are not normal (e.g., perpendicular) to one another.

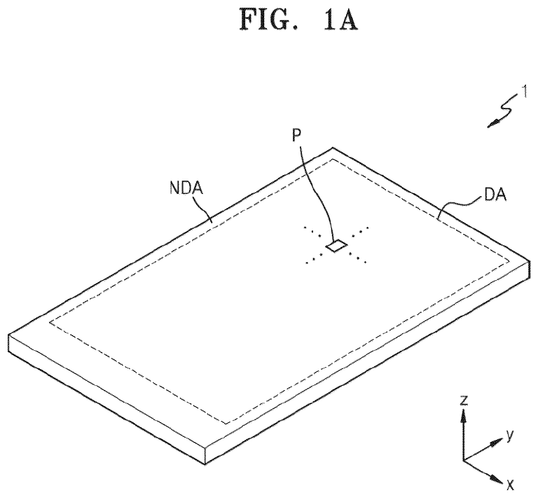

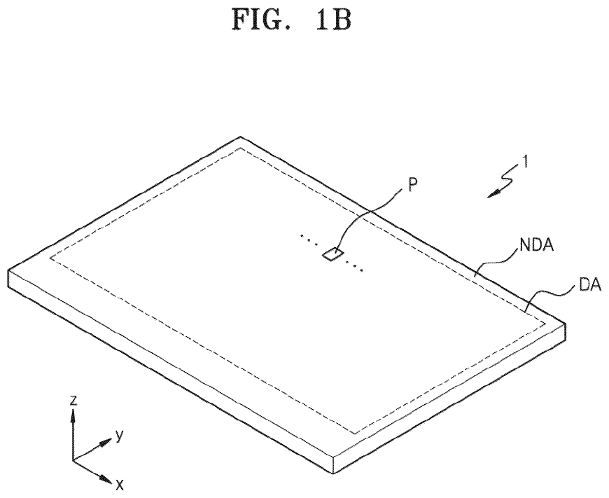

FIGS. 1A and 1B are each a schematic perspective view of a display apparatus 1 according to one or more embodiments of the present disclosure.

Referring to FIGS. 1A and 1B, the display apparatus 1 may include a display area DA and a non-display area NDA outside the display area DA. The display area DA may be configured to display images through pixels P arranged in the display area DA. The non-display area NDA is arranged outside the display area DA and does not display images. The non-display area NDA may be around (e.g., surround) the display area DA entirely. A driver and/or the like configured to provide electrical signals or power to the display area DA may be arranged in the non-display area NDA. A pad may be arranged in the non-display area NDA, wherein the pad is a region to which electronic elements or a printed circuit board may be electrically connected.

In one or more embodiments, although FIG. 1A shows that the display area DA is a polygon (e.g., a quadrangle) in which a length thereof in an x direction is less than a length thereof in a y direction, FIG. 1B shows that the display area DA is a polygon (e.g., a quadrangle) in which a length thereof in the y direction is less than a length thereof in the x direction according to one or more embodiments. Although FIGS. 1A and 1B show the display area DA is approximately quadranglar, the present disclosure is not limited thereto. In one or more embodiments, the display area DA may have one or more suitable shapes such as an N-gon (where N is a natural number of 3 or more), a circle, or an ellipse. Although it is shown in FIGS. 1A and 1B that the display area DA has a shape in which a corner of the display area DA includes a vertex at which a straight line meets a straight line, the display area DA may have a polygon having round corners.

Hereinafter, for convenience of description, although embodiments in which the display apparatus 1 is a smartphone are described, the display apparatus 1 according to the present disclosure is not limited thereto. The display apparatus 1 is applicable to one or more suitable products including televisions, notebook computers, monitors, advertisement boards, Internet of things (IoT) devices, as well as portable electronic apparatuses including mobile phones, smartphones, tablet personal computers (PCs), mobile communication terminals, electronic organizers, electronic books, portable multimedia players (PMPs), navigational units, and/or ultra mobile personal computers (UMPCs). In one or more embodiments, the display apparatus 1 is applicable to wearable devices including smartwatches, watchphones, glasses-type or kind displays, and/or head-mounted displays (HMDs). In addition, in one or more embodiments, the display apparatus 1 is applicable to a display screen in instrument panels for automobiles, center fascias for automobiles, center information displays (CIDs) arranged on a dashboard, room mirror displays that replace side mirrors of automobiles, and/or displays of an entertainment system arranged on the backside of front seats for backseat passengers in automobiles.

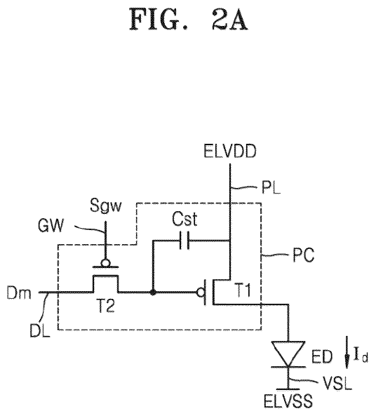

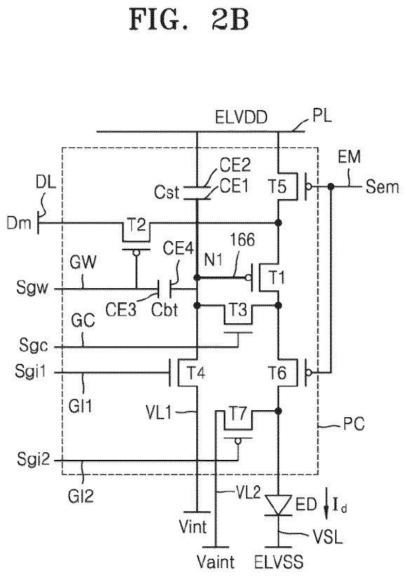

FIGS. 2A and 2B are each a schematic equivalent circuit diagram of a light-emitting element corresponding to one of the pixels of the display apparatus and a pixel circuit electrically connected to the relevant light-emitting element according to one or more embodiments of the present disclosure.

Referring to FIG. 2A, a light-emitting element ED may be electrically connected to a pixel circuit PC, and the pixel circuit PC may include a first transistor T1, a second transistor T2, and a storage capacitor Cst. A pixel electrode (e.g., an anode) of the light-emitting element ED may be electrically connected to the first transistor T1, and an opposite electrode (e.g., a cathode) may be electrically connected to an auxiliary line VSL and may receive a voltage corresponding to a common voltage ELVSS through the auxiliary line VSL.

The second transistor T2 is configured to transfer a data signal Dm to the first transistor T1 according to a scan signal Sgw input through a scan line GW, wherein the data signal Dm is input through a data line DL.

The storage capacitor Cst may be connected to the second transistor T2 and a driving voltage line PL and configured to store a voltage corresponding to a difference between a voltage transferred from the second transistor T2 and a driving voltage ELVDD supplied to the driving voltage line PL.

The first transistor T1 may be connected to the driving voltage line PL and the storage capacitor Cst and configured to control a driving current I_{d} according to the voltage stored in the storage capacitor Cst, the driving current I_{d} flowing from the driving voltage line PL to the light-emitting element ED. The light-emitting element ED may be configured to emit light having a preset brightness corresponding to the driving current I_{d}.

Although it is described with reference to FIG. 2A that the pixel circuit PC includes two transistors and one storage capacitor, the present disclosure is not limited thereto.

FIG. 2B is a schematic equivalent circuit diagram of a light-emitting element corresponding to one of pixels of the display apparatus 1 and the pixel circuit PC electrically connected to the relevant light-emitting element according to one or more embodiments of the present disclosure.

Referring to FIG. 2B, the pixel circuit PC may include seven transistors and two capacitors.

The pixel circuit PC may include first to seventh transistors T1, T2, T3, T4, T5, T6, and T7, a storage capacitor Cst, and a boost capacitor Cbt. In one or more embodiments, the pixel circuit PC may not include (e.g., may exclude) the boost capacitor Cbt. A pixel electrode (e.g., an anode) of the light-emitting element ED may be electrically connected to the first transistor T1 through the seventh transistor T7, and an opposite electrode (e.g., a cathode) may be electrically connected to the auxiliary line VSL and may receive a voltage corresponding to a common voltage ELVSS through the auxiliary line VSL.

Some of the transistors T1, T2, T3, T4, T5, T6, and T7 may be n-channel metal oxide semiconductor (NMOS) field-effect transistors (n-channel MOSFETs), and the rest may be p-channel metal oxide semiconductor (PMOS) field-effect transistors (p-channel MOSFETs). In one or more embodiments, as shown in FIG. 2B, the third and fourth transistors T3 and T4 may be n-channel MOSFETs, and the rest may be p-channel MOSFETs. As an example, the third and fourth transistors T3 and T4 may be n-channel MOSFETs including an oxide-based semiconductor material, and the rest may be p-channel MOSFETs including a silicon-based semiconductor material. In one or more embodiments, the third, fourth, and seventh transistors T3, T4, and T7 may be n-channel MOSFETs, and the rest may be p-channel MOSFETs.

The first to seventh transistors T1, T2, T3, T4, T5, T6, and T7, the storage capacitor Cst, and the boost capacitor Cbt may be connected to signal lines. The signal lines may include an emission control line EM, a compensation gate line GC, a first initialization gate line GI1, a second initialization gate line GI2, and the data line DL. The pixel circuit PC may be electrically connected to a voltage line, for example, the driving voltage line PL, a first initialization voltage line VL1, and a second initialization voltage line VL2.

The first transistor T1 may be a driving transistor. A first gate electrode of the first transistor T1 may be connected to the storage capacitor Cst, a first electrode of the first transistor T1 may be electrically connected to the driving voltage line PL through the fifth transistor T5, and a second electrode of the first transistor T1 may be electrically connected to a first electrode (e.g., an anode) of the light-emitting element ED through the sixth transistor T6. One of the first electrode or the second electrode of the first transistor T1 may be a source electrode, and the other may be a drain electrode. The first transistor T1 may be configured to supply the driving current I_{d} to the light-emitting element ED according to a switching operation of the second transistor T2.

The second transistor T2 may be a switching transistor. A second gate electrode of the second transistor T2 is connected to the scan line GW, a first electrode of the second transistor T2 is connected to the data line DL, and a second electrode of the second transistor T2 is connected to the first electrode of the first transistor T1 and electrically connected to the driving voltage line PL through the fifth transistor T5. One of the first electrode or the second electrode of the second transistor T2 may be a source electrode, and the other may be a drain electrode. The second transistor T2 may be turned on according to a scan signal Sgw transferred through the scan line GW and may perform a switching operation of transferring a data signal Dm to the first electrode of the first transistor T1, wherein the data signal Dm is transferred through the data line DL.

The third transistor T3 may be a compensation transistor configured to compensate for a threshold voltage of the first transistor T1. A third gate electrode of the third transistor T3 is connected to a compensation gate line GC. A first electrode of the third transistor T3 is connected to a lower electrode CE1 of the storage capacitor Cst through a node connection line 166, and connected to the first gate electrode of the first transistor T1. A first electrode of the third transistor T3 may be connected to the fourth transistor T4. A second electrode of the third transistor T3 is connected to the second electrode of the first transistor T1 and electrically connected to the first electrode (e.g., the anode) of the light-emitting element ED through the sixth transistor T6. One of the first electrode or the second electrode of the third transistor T3 may be a source electrode, and the other may be a drain electrode.

The third transistor T3 is turned on according to a compensation signal Sgc transferred through the compensation gate line GC, and diode-connects the first transistor T1 by electrically connecting the first gate electrode to the second electrode (e.g., the drain electrode) of the first transistor T1.

The fourth transistor T4 may be a first initialization transistor configured to initialize the first gate electrode of the first transistor T1. A fourth gate electrode of the fourth transistor T4 is connected to a first initialization gate line GI1. A first electrode of the fourth transistor T4 is connected to a first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode or the second electrode of the fourth transistor T4 may be a source electrode, and the other may be a drain electrode. The fourth transistor T4 may be turned on according to a first initialization signal Sgi1 transferred through the first initialization gate line GI1 and may perform an initialization operation of initializing the voltage of the first gate electrode of the first transistor T1 by transferring a first initialization voltage Vint to the first gate electrode of the driving transistor T1.

The fifth transistor T5 may be an operation control transistor. A fifth gate electrode of the fifth transistor T5 is connected to the emission control line EM, a first electrode of the fifth transistor T5 is connected to the driving voltage line PL, and a second electrode of the fifth transistor T5 is connected to the first electrode of the first transistor T1 and the second electrode of the second transistor T2. One of the first electrode or the second electrode of the fifth transistor T5 may be a source electrode, and the other may be a drain electrode.

The sixth transistor T6 may be an emission control transistor. A sixth gate electrode of the sixth transistor T6 is connected to the emission control line EM, a first electrode of the sixth transistor T6 is connected to the second electrode of the first transistor T1 and the second electrode of the third transistor T3, and a second electrode of the sixth transistor T6 is electrically connected to a second electrode of the seventh transistor T7 and the first electrode (e.g., the anode) of the light-emitting element ED. One of the first electrode or the second electrode of the sixth transistor T6 may be a source electrode, and the other may be a drain electrode.

The fifth transistor T5 and the sixth transistor T6 may be concurrently (e.g., simultaneously) turned on according to an emission control signal Sem transferred through the emission control line EM, the driving voltage ELVDD is transferred to the light-emitting element ED, and the driving current I_{d} flows through the light-emitting element ED.

The seventh transistor T7 may be a second initialization transistor configured to initialize the first electrode (e.g., an anode) of the light-emitting element ED. A seventh gate electrode of the seventh transistor T7 is connected to a second initialization gate line GI2. A first electrode of the seventh transistor T7 is connected to the second initialization voltage line VL2. A second electrode of the seventh transistor T7 is connected to the second electrode of the sixth transistor T6 and the first electrode (e.g., the anode) of the light-emitting element ED. The seventh transistor T7 may be turned on according to a second initialization signal Sgi2 transferred through the second initialization gate line GI2, and configured to initialize the first electrode of the light-emitting element ED by transferring a second initialization voltage Vaint to the first electrode (e.g., the anode) of the light-emitting element ED.

In one or more embodiments, the second initialization voltage line VL2 may be a next scan line. As an example, the second initialization gate line GI2 connected to the seventh transistor T7 of the pixel circuit PC and arranged in an i-th row (i is a natural number), may correspond to a scan line of the pixel circuit PC arranged in an (i+1)-th row. In one or more embodiments, the second initialization voltage line VL2 may be the emission control line EM. As an example, the emission control line EM may be electrically connected to the fifth to seventh transistors T5, T6, and T7.

The storage capacitor Cst includes the lower electrode CE1 and an upper electrode CE2. The lower electrode CE1 of the storage capacitor Cst is connected to the first gate electrode of the first transistor T1, and the upper electrode CE2 of the storage capacitor Cst is connected to the driving voltage line PL. The storage capacitor Cst may be configured to store charge corresponding to a difference between a voltage of the first gate electrode of the first transistor T1 and the driving voltage ELVDD.

The boost capacitor Cbt includes a third electrode CE3 and a fourth electrode CE4. The third electrode CE3 may be connected to the second gate electrode of the second transistor T2 and the scan line GW, and the fourth electrode CE4 may be connected to the first electrode of the third transistor T3 and the node connection line 166. The boost capacitor Cbt may raise the voltage of a first node N1 if (e.g., when) a scan signal Sgw supplied to the scan line GW is turned off. When the voltage of the first node N1 is raised, a black grayscale may be clearly expressed.

The first node N1 may be a region where the first gate electrode of the first transistor T1, the first electrode of the third transistor T3, the second electrode of the fourth transistor T4, and the fourth electrode CE4 of the boost capacitor Cbt are connected to each other.

In one or more embodiments, it is described in FIG. 2B that the third and fourth transistors T3 and T4 are n-channel MOSFETs, and the first, second, fifth to seventh transistors T1, T2, T5, T6, and T7 are p-channel MOSFETs. The first transistor T1 directly influencing the brightness of the display apparatus displaying images may be configured to include a semiconductor layer including polycrystalline silicon having high reliability, and thus, a high-resolution display apparatus may be implemented through this configuration.

Although it is described in FIG. 2B that some of the transistors are n-channel MOSFETS (NMOSFETs) and the rest are p-channel MOSFETs (PMOSFETs), the present disclosure is not limited thereto. In one or more embodiments, the pixel circuit PC may include three transistors and all of the three transistors may be NMOSFETs. However, one or more suitable modifications may be made.

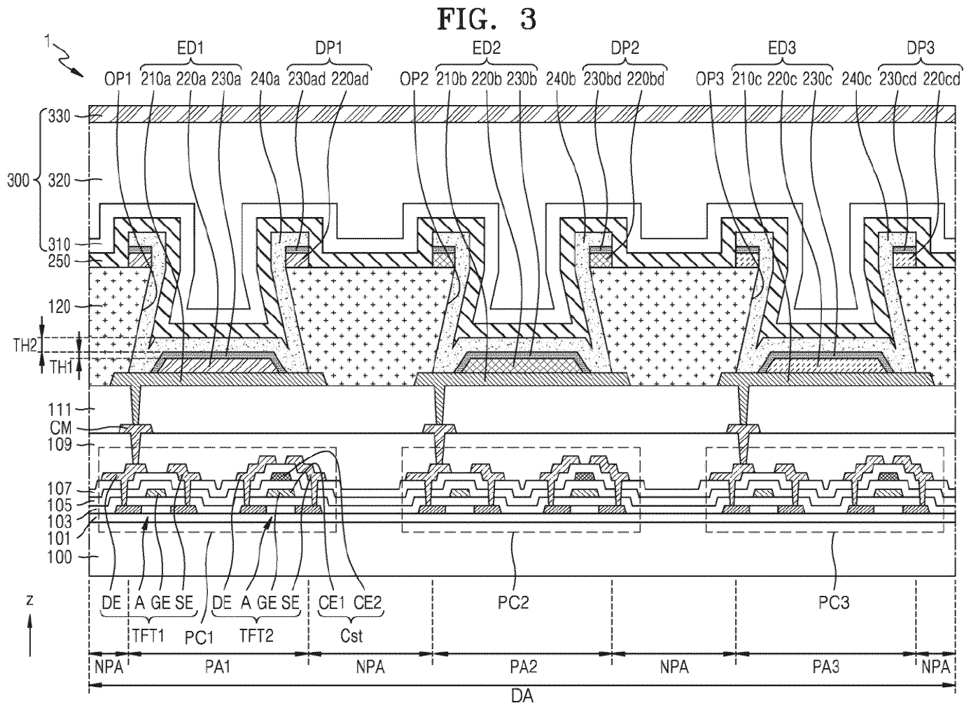

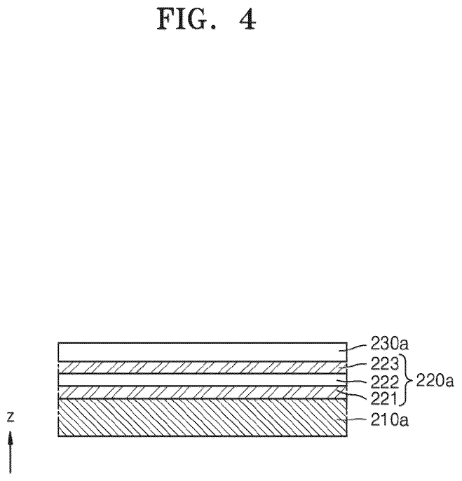

FIG. 3 is a schematic cross-sectional view of the display apparatus 1 according to one or more embodiments of the present disclosure. FIG. 3 shows a cross-section of the display apparatus 1 in the display area DA. FIG. 4 is a cross-sectional view of a stack structure of a first light-emitting element ED1 of the display apparatus 1 of FIG. 3, according to one or more embodiments of the present disclosure.

Referring to FIGS. 3 and 4, the display apparatus 1 may include a substrate 100, first to third pixel circuits PC1, PC2, and PC3 on the substrate 100, first to third light-emitting elements ED1, ED2, and ED3 over the first to third pixel circuits PC1, PC2, and PC3, and a thin-film encapsulation layer 300 on the first to third light-emitting elements ED1, ED2, and ED3. The display apparatus 1 may further include first to third dummy patterns DP1, DP2, and DP3, and first to third auxiliary electrode patterns 240a, 240b, and 240c, and an auxiliary electrode layer 250.

The display apparatus 1 may include first to third pixel areas PA1, PA2, and PA3 and include a non-pixel area NPA between the adjacent pixel areas. The planar shape of the display apparatus 1 may be actually the same as a planar shape of the substrate 100. Accordingly, if (e.g., when) the display apparatus 1 includes the first to third pixel areas PA1, PA2, and PA3 and the non-pixel area NPA, it may represent that the substrate 100 includes the first to third pixel areas PA1, PA2, and PA3 and the non-pixel area NPA. The first to third light-emitting elements ED1, ED2, and ED3 may be arranged over (on) the substrate 100. The first to third light-emitting elements ED1, ED2, and ED3 may be respectively arranged in the first to third pixel areas PA1, PA2, and PA3.

The substrate 100 may include glass or polymer resin. The substrate 100 may have a structure in which a base layer including polymer resin and an inorganic barrier layer are stacked. The polymer resin may include polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate, cellulose tri acetate (TAC), cellulose acetate propionate (CAP), and/or the like.

A buffer layer 101 may be arranged on the upper surface of the substrate 100. The buffer layer 101 may prevent or reduce the likelihood of impurities penetrating a semiconductor layer of a transistor. The buffer layer 101 may include an inorganic insulating material such as silicon nitride, silicon oxynitride, and/or silicon oxide, and include a single layer or a multi-layer including the above inorganic insulating materials.

The first to third pixel circuits PC1, PC2, and PC3 may be arranged on the buffer layer 101. The first to third pixel circuits PC1, PC2, and PC3 may be arranged between the substrate 100 and the first to third light-emitting elements ED1, ED2, and ED3. The first to third pixel circuits PC1, PC2, and PC3 may each include the transistor and the storage capacitor described above with reference to FIG. 2A or 2B. In one or more embodiments, FIG. 3 shows a first thin-film transistor TFT1, a second thin-film transistor TFT2, and a storage capacitor Cst of the first pixel circuit PC1. Because each of the second pixel circuit PC2 and the third pixel circuit PC3 may have substantially the same structure as that of the first pixel circuit PC1, the structure of the first pixel circuit PC1 is mainly described, for convenience of description.

Each of the first thin-film transistor TFT1 and the second thin-film transistor TFT2 may include a semiconductor layer A on the buffer layer 101, and a gate electrode GE overlapping a channel region of the semiconductor layer A. Each of the first thin-film transistor TFT1 and the second thin-film transistor TFT2 may further include a source electrode SE and/or a drain electrode DE electrically connected to the semiconductor layer A. In one or more embodiments, the first thin-film transistor TFT1 may be the sixth transistor T6 of FIG. 2B, and the second thin-film transistor TFT2 may be the first transistor T1 of FIG. 2B.

The semiconductor layer A may be arranged on the buffer layer 101. The semiconductor layer A may include a silicon-based semiconductor material, for example, polycrystalline silicon. The semiconductor layer A may include a channel region, a first region, and a second region, the first region and the second region being on two opposite sides of the channel region. The first region and the second region are regions including impurities of higher concentration than that of the channel region. One of the first region or the second region may correspond to a source region, and the other may correspond to a drain region.

The gate electrode GE may be arranged over the semiconductor layer A with a gate insulating layer 103 therebetween. The gate electrode GE may overlap the channel region of the semiconductor layer A. The gate electrode GE may include a low-resistance metal material. The gate electrode GE may include a conductive material including molybdenum (Mo), aluminum (Al), copper (Cu), and/or titanium (Ti) and may have a single-layered structure or a multi-layered structure including the above materials.

The first gate insulating layer 103 may be arranged on the buffer layer 101. The first gate insulating layer 103 may be arranged between the semiconductor layer A and the gate electrode GE. The first gate insulating layer 103 may include an inorganic insulating material such as silicon nitride, silicon oxynitride, and/or silicon oxide, and may include a single layer or a multi-layer including the above inorganic insulating materials.

A first interlayer insulating layer 105 may be arranged on the first gate insulating layer 103. The first interlayer insulating layer 105 may cover the gate electrode GE. The first interlayer insulating layer 105 may include an inorganic insulating material such as silicon nitride, silicon oxynitride, and/or silicon oxide, and may include a single layer or a multi-layer including the above inorganic insulating materials.

The storage capacitor Cst may include the lower electrode CE1 and the upper electrode CE2 overlapping each other. The upper electrode CE2 of the storage capacitor Cst may be arranged on the first interlayer insulating layer 105. In one or more embodiments, the upper electrode CE2 may overlap the gate electrode GE of the second thin-film transistor TFT2. In such embodiments, the gate electrode GE of the second thin-film transistor TFT2 and the upper electrode CE2 overlapping each other with the first interlayer insulating layer 105 therebetween may configure the storage capacitor Cst. For example, the gate electrode GE of the second thin-film transistor TFT2 may serve as the lower electrode CE1 of the storage capacitor Cst. Likewise, the storage capacitor Cst and the second thin-film transistor TFT2 may overlap each other.

The upper electrode CE2 of the storage capacitor Cst may include a conductive material of a low-resistance material such as molybdenum (Mo), aluminum (Al), copper (Cu) and/or titanium (Ti), and may have a single-layered structure or a multi-layered structure including the above materials.

A second interlayer insulating layer 107 may be arranged on the storage capacitor Cst. The second interlayer insulating layer 107 may be arranged on the first interlayer insulating layer 105. The second interlayer insulating layer 107 may include an inorganic insulating material such as silicon nitride, silicon oxynitride, and/or silicon oxide, and may include a single-layered structure or a multi-layered structure including the above inorganic insulating materials.

The source electrode SE and/or the drain electrode DE electrically connected to the semiconductor layer A may be arranged on the second interlayer insulating layer 107. The source electrode SE and/or the drain electrode DE may include aluminum (Al), copper (Cu), and/or titanium (Ti), and may include a single layer or a multi-layer including the above materials.

A first organic insulating layer 109 may be arranged on the first to third pixel circuits PC1, PC2, and PC3. The first organic insulating layer 109 may include an organic insulating material such as acryl, benzocyclobutene (BCB), polyimide, and/or hexamethyldisiloxane (HMDSO). The first organic insulating layer 109 serves as a layer for providing a flat upper surface and may be denoted as a first planarization layer.

A connection metal CM may be arranged on the first organic insulating layer 109. The connection metal CM may include aluminum (Al), copper (Cu), and/or titanium (Ti), and may include a single layer or a multi-layer including the above materials.

A second organic insulating layer 111 may be arranged between the connection metal CM and first to third pixel electrodes 210a, 210b, and 210c. The second organic insulating layer 111 may include an organic insulating material such as acryl, benzocyclobutene (BCB), polyimide, and/or hexamethyldisiloxane (HMDSO). The second organic insulating layer 111 serves as a layer for providing a flat upper surface and may be denoted as a second planarization layer.

According to one or more embodiments described with reference to FIG. 3, although it is shown that the first to third pixel circuits PC1, PC2, and PC3 are respectively electrically connected to the first to third pixel electrodes 210a, 210b, and 210c through the connection metals CM, the connection metals CM may not be provided and an organic insulating layer may be arranged between the first to third pixel circuits PC1, PC2, and PC3 and the first to third pixel electrodes 210a, 210b, and 210c. In one or more embodiments, three or more organic insulating layers may be arranged between the first to third pixel circuits PC1, PC2, and PC3 and the first to third pixel electrodes 210a, 210b, and 210c, and the first to third pixel circuits PC1, PC2, and PC3 may be respectively electrically connected to the first to third pixel electrodes 210a, 210b, and 210c through a plurality of connection metals.

The first to third light-emitting elements ED1, ED2, and ED3 respectively electrically connected to the first to third pixel circuits PC1, PC2, and PC3 may each have a stack structure of a pixel electrode, an intermediate layer, and an opposite electrode.

As an example, the first light-emitting element ED1 may include the first pixel electrode 210a, a first intermediate layer 220a, and a first opposite electrode 230a. The second light-emitting element ED2 may include the second pixel electrode 210b, a second intermediate layer 220b, and a second opposite electrode 230b. The third light-emitting element ED3 may include the third pixel electrode 210c, a third intermediate layer 220c, and a third opposite electrode 230c. The first pixel electrode 210a, the second pixel electrode 210b, and the third pixel electrode 210c may be respectively and electrically connected to the first pixel circuit PC1, the second pixel circuit PC2, and the third pixel circuit PC3.

The first to third pixel electrodes 210a, 210b, and 210c may be arranged on the second organic insulating layer 111. The first to third pixel electrodes 210a, 210b, and 210c may each include a metal and/or conductive oxide. The first to third pixel electrodes 210a, 210b, and 210c may include reflective electrodes. As an example, one or more of the first to third pixel electrodes 210a, 210b, and 210c may include a reflective layer including Ag, Mg, Al, Pt, Pd, Au, Ni, Nd, Ir, Cr, and/or compounds thereof. One or more of the first to third pixel electrodes 210a, 210b, and 210c may further include a transparent or semi-transparent conductive layer under and/or on the reflective layer. The transparent or semi-transparent conductive layer may include, for example, at least one of indium tin oxide (ITO), indium zinc oxide (IZO), zinc oxide (ZnO), indium oxide (In₂O₃), indium gallium oxide (IGO), and/or aluminum zinc oxide (AZO). In one or more embodiments, each of the first to third pixel electrodes 210a, 210b, and 210c may have a structure in which an ITO layer, an Ag layer, and an ITO layer are sequentially stacked. The first to third pixel electrodes 210a, 210b, and 210c may be electrically connected to the connection metal CM through contact holes in the second organic insulating layer 111.

The pixel-defining layer 120 may be arranged on the second organic insulating layer 111. The pixel-defining layer 120 may be arranged on the first to third pixel electrodes 210a, 210b, and 210c, and may include a first opening OP1 exposing a portion of the first pixel electrode 210a, a second opening OP2 exposing a portion of the second pixel electrode 210b, and a third opening OP3 exposing a portion of the third pixel electrode 210c. For example, at least a portion of the upper surfaces of the first to third pixel electrodes 210a, 210b, and 210c may be exposed by the first to third openings OP1, OP2, and OP3 defined in the pixel-defining layer 120. Emission areas of the respective pixels may be defined by the first to third openings OP1, OP2, and OP3 exposing at least a portion of the first to third pixel electrodes 210a, 210b, and 210c.

The pixel-defining layer 120 may have a reverse taper shape in a cross-sectional view. In the present specification, a reverse taper shape may be defined as a shape in which the width of the upper surface of the pixel-defining layer 120 is greater than the width of the lower surface of the pixel-defining layer 120 in a thickness direction of the display apparatus 1. In one or more embodiments, the reverse taper shape may be defined as a shape in which the width of the pixel-defining layer 120 is reduced in a direction (e.g., a-z direction) toward the upper surface of the substrate 100. In one or more embodiments, the reverse taper shape may be defined as a shape in which the width of each of the first to third openings OP1, OP2, and OP3 is greater in the lower region located relatively close to the substrate 100, and is smaller in the upper region located relatively further away from the substrate 100.

Although it is shown in FIG. 3 that the pixel-defining layer 120 is a trapezoidal shape, this is an example and the present disclosure is not limited thereto. In one or more embodiments, the pixel-defining layer 120 may have a reverse taper shape, and the corners of the upper surface thereof may be rounded. In one or more embodiments, the pixel-defining layer 120 may have an undercut structure. As an example, the upper region of the pixel-defining layer 120 may protrude more than the lower region to form an undercut structure. In one or more embodiments, although the slope of the lateral surface of the pixel-defining layer 120 is constant, the present disclosure is not limited thereto. As another example, the pixel-defining layer 120 may have an undercut structure including regions with different side slopes.

The pixel-defining layer 120 may be configured to prevent or reduce arcs and/or the like from occurring at the edges of the first to third pixel electrodes 210a, 210b, and 210c by increasing a distance between the edges of the first to third pixel electrodes 210a, 210b, and 210c and the opposite electrode.

In one or more embodiments, the pixel-defining layer 120 may include an organic material such as photosensitive polyimide (PSPI), polyimide, polyamide, acrylic resin, benzocyclobutene, and/or phenolic resin. In one or more embodiments, the pixel-defining layer 120 may include a photosensitive organic material. In one or more embodiments, the pixel-defining layer 120 may include a negative type or kind photosensitive organic material.

The first to third intermediate layers 220a, 220b, and 220c may be respectively arranged on the first to third pixel electrodes 210a, 210b, and 210c. The first intermediate layer 220a may be arranged in the first opening OP1 of the pixel-defining layer 120 and may overlap the first pixel electrode 210a. The first intermediate layer 220a arranged between the first opposite electrode 230a and the first pixel electrode 210a may be configured to emit light of a first color. The second intermediate layer 220b may be arranged in the second opening OP2 of the pixel-defining layer 120 and may overlap the second pixel electrode 210b. The second intermediate layer 220b arranged between the second opposite electrode 230b and the second pixel electrode 210b may be configured to emit light of a second color. The third intermediate layer 220c may be arranged in the third opening OP3 of the pixel-defining layer 120 and may overlap the third pixel electrode 210c. The third intermediate layer 220c arranged between the third opposite electrode 230c and the third pixel electrode 210c may be configured to emit light of a third color.

As shown in FIG. 4, the first intermediate layer 220a may include a first common layer 221, a first emission layer 222, and a second common layer 223. The first intermediate layer 220a may include the first common layer 221 arranged between the first pixel electrode 210a and the first emission layer 222, and/or the second common layer 223 arranged between the first emission layer 222 and the first opposite electrode 230a.

The first emission layer 222 may include a polymer organic material or a low-molecular weight organic material emitting light having a preset color (e.g., red, green, or blue). In one or more embodiments, the first emission layer 222 may include an inorganic material or quantum dots.

The first common layer 221 may include a hole transport layer (HTL) and/or a hole injection layer (HIL). The second common layer 223 may include an electron transport layer (ETL) and/or an electron injection layer (EIL). The first common layer 221 and the second common layer 223 may each include an organic material.

The structure of each of the second light-emitting element ED2 and the third light-emitting element ED3 may include substantially the same structure and material except that a second emission layer of the second intermediate layer 220b and a third emission layer of the third intermediate layer 220c are configured to emit light of different colors from light of the color emitted from the first emission layer 222 of the first intermediate layer 220a and thus may include materials configured to emit light of different colors. For example, similar to the first light-emitting element ED1 described with reference to FIG. 4, each of the second light-emitting element ED2 and the third light-emitting element ED3 may include an emission layer and the first and/or second common layers.

The first opposite electrode 230a may be arranged in the first opening OP1 of the pixel-defining layer 120 and may be arranged on the first intermediate layer 220a. The first opposite electrode 230a may cover the upper surface of the first intermediate layer 220a. The second opposite electrode 230b may be arranged in the second opening OP2 of the pixel-defining layer 120 and may be arranged on the second intermediate layer 220b. The second opposite electrode 230b may cover the upper surface of the second intermediate layer 220b. The third opposite electrode 230c may be arranged in the third opening OP3 of the pixel-defining layer 120 and may be arranged on the third intermediate layer 220c. The third opposite electrode 230c may cover the upper surface of the third intermediate layer 220c. The first to third opposite electrodes 230a, 230b, and 230c may respectively have patterned shapes, for example, island pattern shapes in regions respectively corresponding to the first to third pixel electrodes 210a, 210b, and 210c.

In one or more embodiments, each of the first to third opposite electrodes 230a, 230b, and 230c may include a transparent or semi-transparent electrode. Each of the first to third opposite electrodes 230a, 230b, and 230c may include a conductive material with a low work function. As an example, each of the first to third opposite electrodes 230a, 230b, and 230c may include a (semi) transparent layer including silver (Ag), magnesium (Mg), aluminum (Al), platinum (Pt), palladium (Pd), gold (Au), and nickel (Ni), neodymium (Nd), iridium (Ir), chromium (Cr), lithium (Li), calcium (Ca), and/or an alloy thereof. In one or more embodiments, each of the first to third opposite electrodes 230a, 230b, and 230c may further include a layer including ITO, IZO, ZnO, and/or In₂O₃ on the (semi) transparent layer including the above materials.

The first dummy pattern DP1, the second dummy pattern DP2, and the third dummy pattern DP3 may be arranged on the pixel-defining layer 120. The first dummy pattern DP1 may be arranged in a first pixel area PA1, the second dummy pattern DP2 may be arranged in a second pixel area PA2, and the third dummy pattern DP3 may be arranged in a third pixel area PA3. As an example, the first dummy pattern DP1 may be arranged to be adjacent to the first light-emitting element ED1, the second dummy pattern DP2 may be arranged to be adjacent to the second light-emitting element ED2, and the third dummy pattern DP3 may be arranged to be adjacent to the third light-emitting element ED3. In one or more embodiments, the first dummy pattern DP1, the second dummy pattern DP2, and the third dummy pattern DP3 may be arranged to be apart (e.g., spaced and/or apart) from each other on the pixel-defining layer 120. The first dummy pattern DP1, the second dummy pattern DP2, and the third dummy pattern DP3 may include substantially the same materials as those of the first intermediate layer 220a, the second intermediate layer 220b, and the third intermediate layer 220c, respectively.

In one or more embodiments, each of the first dummy pattern DP1, the second dummy pattern DP2, and the third dummy pattern DP3 may include at least one dummy intermediate layer and at least one dummy opposite electrode. The first dummy pattern DP1 may include a first dummy intermediate layer 220ad and a first dummy opposite electrode 230ad. The second dummy pattern DP2 may include a second dummy intermediate layer 220bd and a second dummy opposite electrode 230bd. The third dummy pattern DP3 may include a third dummy intermediate layer 220cd and a third dummy opposite electrode 230cd.

The first to third dummy intermediate layers 220ad, 220bd, and 220cd may be respectively separated and apart from the first to third intermediate layers 220a, 220b, and 220c by the reverse taper shapes of the pixel-defining layer 120. As an example, the first intermediate layer 220a may be formed by a deposition process. In the case where the pixel-defining layer 120 has a reverse taper shape, a material for forming the first intermediate layer 220a may be deposited on the first pixel electrode 210a and deposited on the upper surface of the pixel-defining layer 120 as shown in FIGS. 3 and 4. The material deposited on the first pixel electrode 210a may correspond to the first intermediate layer 220a, and the material deposited on the upper surface of the pixel-defining layer 120 may correspond to the first dummy intermediate layer 220ad. Similar to the first dummy intermediate layer 220ad, the second dummy intermediate layer 220bd of the second dummy pattern DP2 and the third dummy intermediate layer 220cd of the third dummy pattern DP3 may be layers in which materials for forming the second intermediate layer 220b and the third intermediate layer 220c, respectively, are deposited on the upper surface of the pixel defining layer 120.

The first dummy intermediate layer 220ad may include the same material (substantially the same material) as a material of the first intermediate layer 220a, the second dummy intermediate layer 220bd may include the same material (substantially the same material) as a material of the second intermediate layer 220b, and the third dummy intermediate layer 220cd may include the same material (substantially the same material) as a material of the third intermediate layer 220c. In one or more embodiments, because the first intermediate layer 220a, the second intermediate layer 220b, and the third intermediate layer 220c respectively include different materials to emit light of different colors, the first dummy intermediate layer 220ad, the second dummy intermediate layer 220bd, and the third dummy intermediate layer 220cd may respectively include different materials.

The first to third dummy opposite layers 230ad, 230bd, and 230cd may be respectively separated and apart from the first to third opposite layers 230a, 230b, and 230c by the reverse taper shapes of the pixel-defining layer 120. As an example, the first opposite layer 230a may be formed by a deposition process. In embodiments in which the pixel-defining layer 120 has a reverse taper shape, a material for forming the first opposite layer 230a may be deposited on the first intermediate layer 220a and deposited on the upper surface of the pixel-defining layer 120. The material deposited on the first intermediate layer 220a may correspond to the first opposite layer 230a, and the material deposited on the upper surface of the pixel-defining layer 120 may correspond to the first dummy opposite electrode 230ad. The first dummy opposite electrode 230ad may be arranged on the first dummy intermediate layer 220ad. Similar to the first dummy opposite electrode 230ad, the second dummy opposite electrode 230bd of the second dummy pattern DP2 and the third dummy opposite electrode 230cd of the third dummy pattern DP3 may be layers in which materials for forming the second opposite electrode 230b and the third opposite electrode 230c, respectively, are deposited on the upper surface of the pixel defining layer 120.

The first dummy opposite electrode 230ad may include the same material (substantially the same material) as a material of the first opposite electrode 230a, the second dummy opposite electrode 230bd may include the same material (substantially the same material) as a material of the second opposite electrode 230b, and the third dummy opposite electrode 230cd may include the same material (substantially the same material) as a material of the third opposite electrode 230c. In one or more embodiments, because the first opposite electrode 230a, the second opposite electrode 230b, and the third opposite electrode 230c may include the same material (substantially the same material), the first dummy opposite electrode 230ad, the second dummy opposite electrode 230bd, and the third dummy opposite electrode 230cd may include the same material (substantially the same material).

A first auxiliary electrode pattern 240a, a second auxiliary electrode pattern 240b, and a third auxiliary electrode pattern 240c may be respectively arranged on the first light-emitting element ED1, the second light-emitting element ED2, and the third light-emitting element ED3. The first auxiliary electrode pattern 240a, the second auxiliary electrode pattern 240b, and the third auxiliary electrode pattern 240c may be respectively arranged on the first dummy pattern DP1, the second dummy pattern DP2, and the third dummy pattern DP3. The first auxiliary electrode pattern 240a, the second auxiliary electrode pattern 240b, and the third auxiliary electrode pattern 240c may be arranged to be apart from each other. As an example, the first auxiliary electrode pattern 240a, the second auxiliary electrode pattern 240b, and the third auxiliary electrode pattern 240c may each have an island pattern shape in a plan view. That is, the first auxiliary electrode 240a, the second auxiliary electrode 240b, and the third auxiliary electrode 240c may be distinct islands (may be individually configured with an island pattern shape) when viewed from above (in a plan view).

The first auxiliary electrode pattern 240a may overlap the first opening OP1 of the pixel-defining layer 120. The first auxiliary electrode pattern 240a may be arranged on the first opposite electrode 230a and the first dummy opposite electrode 230ad. The first auxiliary electrode pattern 240a may be arranged on the first opposite electrode 230a and electrically connected to the first opposite electrode 230a. In one or more embodiments, the first auxiliary electrode pattern 240a may be arranged on the lateral surface of the pixel-defining layer 120 defining the first opening OP1. As an example, the first auxiliary electrode pattern 240a may be arranged along the profile of the lateral surface of the pixel-defining layer 120 defining the first opening OP1. As an example, the first auxiliary electrode pattern 240a may be in contact with the lateral surface of the pixel-defining layer 120 defining the first opening OP1. The first auxiliary electrode pattern 240a may cover the upper surface of the first opposite electrode 230a, the lateral surface of the pixel-defining layer 120 defining the first opening OP1, and the upper surface of the first dummy pattern DP1 (e.g., the upper surface of the first dummy opposite electrode 230ad). In one or more embodiments, the first auxiliary electrode pattern 240a may cover the inner surface of the first dummy pattern DP1. The inner surface of the first dummy pattern DP1 may be defined as a lateral surface facing (e.g., defining) the first opening OP1 of the pixel-defining layer 120 in a cross-sectional view. The first auxiliary electrode pattern 240a may cover the inner surface of the first dummy intermediate layer 220ad and the inner surface of the first dummy opposite electrode 230ad.

The second auxiliary electrode pattern 240b may overlap the second opening OP2 of the pixel-defining layer 120. The second auxiliary electrode pattern 240b may be arranged on the second opposite electrode 230b and the second dummy opposite electrode 230bd. The second auxiliary electrode pattern 240b may be arranged on the second opposite electrode 230b and electrically connected to the second opposite electrode 230b. In one or more embodiments, the second auxiliary electrode pattern 240b may be arranged on the lateral surface of the pixel-defining layer 120 defining the second opening OP2. As an example, the second auxiliary electrode pattern 240b may be arranged along the profile of the lateral surface of the pixel-defining layer 120 defining the second opening OP2. As an example, the second auxiliary electrode pattern 240b may be in contact with the lateral surface of the pixel-defining layer 120 defining the second opening OP2. The second auxiliary electrode pattern 240b may cover the upper surface of the second opposite electrode 230b, the lateral surface of the pixel-defining layer 120 defining the second opening OP2, and the upper surface of the second dummy pattern DP2 (e.g., the upper surface of the second dummy opposite electrode 230bd). The second auxiliary electrode pattern 240b may cover the inner surface of the second dummy pattern DP2. The inner surface of the second dummy pattern DP2 may be defined as a lateral surface facing (e.g., defining) the second opening OP2 of the pixel-defining layer 120 in a cross-sectional view. The second auxiliary electrode pattern 240b may cover the inner surface of the second dummy intermediate layer 220bd and the inner surface of the second dummy opposite electrode 230bd.

The third auxiliary electrode pattern 240c may overlap the third opening OP3 of the pixel-defining layer 120. The third auxiliary electrode pattern 240c may be arranged on the third opposite electrode 230c and the third dummy opposite electrode 230cd. The third auxiliary electrode pattern 240c may be arranged on the third opposite electrode 230c and electrically connected to the third opposite electrode 230c. In one or more embodiments, the third auxiliary electrode pattern 240c may be arranged on the lateral surface of the pixel-defining layer 120 defining the third opening OP3. As an example, the third auxiliary electrode pattern 240c may be arranged along the profile of the lateral surface of the pixel-defining layer 120 defining the third opening OP3. As an example, the third auxiliary electrode pattern 240c may be in contact with the lateral surface of the pixel-defining layer 120 defining the third opening OP3. The third auxiliary electrode pattern 240c may cover the upper surface of the third opposite electrode 230c, the lateral surface of the pixel-defining layer 120 defining the third opening OP3, and the upper surface of the third dummy pattern DP3 (e.g., the upper surface of the third dummy opposite electrode 230cd). The third auxiliary electrode pattern 240c may cover the inner surface of the third dummy pattern DP3. The inner surface of the third dummy pattern DP3 may be defined as a lateral surface facing (e.g., defining) the third opening OP3 of the pixel-defining layer 120 in a cross-sectional view. The third auxiliary electrode pattern 240c may cover the inner surface of the third dummy intermediate layer 220cd and the inner surface of the third dummy opposite electrode 230cd.

A thickness TH2 of the first auxiliary electrode pattern 240a may be greater than a thickness TH1 of the first opposite electrode 230a. Similarly, a thickness of the second auxiliary electrode pattern 240b may be greater than a thickness of the second opposite electrode 230b, and a thickness of the third auxiliary electrode pattern 240c may be greater than a thickness of the third opposite electrode 230c. As an example, the thicknesses of the first to third auxiliary electrode patterns 240a, 240b, and 240c may be 700 Å or more. As an example, the thicknesses of the first to third auxiliary electrode patterns 240a, 240b, and 240c may be 1000 Å or more. Because the thicknesses of the first to third auxiliary electrode patterns 240a, 240b, and 240c are formed relatively thick, the first to third intermediate layers 220a, 220b, and 220c formed under the first to third auxiliary electrode patterns 240a, 240b, and 240c may be prevented from being damaged or the likelihood of damage may be reduced during the manufacturing process.

In one or more embodiments, each of the first to third auxiliary electrode patterns 240a, 240b, and 240c may include a conductive material. In one or more embodiments, each of the first to third auxiliary electrode patterns 240a, 240b, and 240c may include a light-transmissive conductive material. The light-transmissive conductive material may include a transparent conductive material or a semi-transparent conductive material. As an example, each of the first to third auxiliary electrode patterns 240a, 240b, and 240c may include at least one of indium tin oxide (ITO), indium zinc oxide (IZO), zinc oxide (ZnO), indium oxide (In₂O₃), indium gallium oxide (IGO), and/or aluminum zinc oxide (AZO).

The auxiliary electrode layer 250 may be integrally formed over the plurality of pixels. For example, the auxiliary electrode layer 250 may be arranged over the first pixel area PA1, the second pixel area PA2, the third pixel area PA3, and an entire non-pixel area NPA. The auxiliary electrode layer 250 may overlap the first light-emitting element ED1, the second light-emitting element ED2, and the third light-emitting element ED3 and may overlap the pixel-defining layer 120. As an example, the auxiliary electrode layer 250 may overlap the pixel-defining layer 120 and may overlap the first to third openings OP1, OP2, and OP3 of the pixel-defining layer 120.

The auxiliary electrode layer 250 may be arranged on the first auxiliary electrode pattern 240a, the second auxiliary electrode pattern 240b, the third auxiliary electrode pattern 240c, and the pixel-defining layer 120. The auxiliary electrode layer 250 may entirely overlap or cover (e.g., overlaps or covers an entirety of) the first auxiliary electrode pattern 240a, the second auxiliary electrode pattern 240b, the third auxiliary electrode pattern 240c, and the pixel-defining layer 120. The auxiliary electrode layer 250 may cover at least a portion of lateral surfaces respectively defining the first to third openings OP1, OP2, and OP3 of the pixel-defining layer 120. The auxiliary electrode layer 250 may be continuously formed to overlap (or cover) the upper surface and lateral surface of each of the first auxiliary electrode pattern 240a, the second auxiliary electrode pattern 240b, the third auxiliary electrode pattern 240c, and the upper surface and lateral surface of the pixel-defining layer 120. The auxiliary electrode layer 250 may be integrally arranged on the first auxiliary electrode pattern 240a, the second auxiliary electrode pattern 240b, the third auxiliary electrode pattern 240c to electrically connect the first auxiliary electrode pattern 240a, the second auxiliary electrode pattern 240b, the third auxiliary electrode pattern 240c to each other. Accordingly, the auxiliary electrode layer 250 may electrically connect the first opposite electrode 230a, the second opposite electrode 230b, and the third opposite electrode 230c to each other. In one or more embodiments, the auxiliary electrode layer 250 may be configured to receive a voltage corresponding to the common voltage ELVSS (see FIG. 2A).

In one or more embodiments, the auxiliary electrode layer 250 may cover the outer surface of the first dummy pattern DP1, the outer surface of the second dummy pattern DP2, and the outer surface of the third dummy pattern DP3. The outer surfaces of the first to third dummy patterns DP1, DP2, and DP3 may be defined as lateral surfaces respectively facing (e.g., opposite to) the inner surfaces of the first to third dummy patterns DP1, DP2, and DP3. As an example, the auxiliary electrode layer 250 may cover the outer surface of the first dummy intermediate layer 220ad, the outer surface of the second dummy intermediate layer 220bd, and the outer surface of the third dummy intermediate layer 220cd. As an example, the auxiliary electrode layer 250 may cover the outer surface of the first dummy opposite electrode 230ad, the outer surface of the second dummy opposite electrode 230bd, and the outer surface of the third dummy opposite electrode 230cd. The auxiliary electrode layer 250 may be in contact with the outer surface of the first dummy pattern DP1, the outer surface of the second dummy pattern DP2, and the outer surface of the third dummy pattern DP3.

The auxiliary electrode layer 250 may include a conductive material. In one or more embodiments, the auxiliary electrode layer 250 may include a light-transmissive conductive material. The light-transmissive conductive material may include a transparent conductive material or a semi-transparent conductive material. As an example, the auxiliary electrode layer 250 may include at least one of indium tin oxide (ITO), indium zinc oxide (IZO), zinc oxide (ZnO), indium oxide (In₂O₃), indium gallium oxide (IGO), and/or aluminum zinc oxide (AZO).

The first to third light-emitting elements ED1, ED2, and ED3 may be encapsulated by the encapsulation layer 300. The thin-film encapsulation layer 300 may include at least one inorganic encapsulation layer and at least one organic encapsulation layer. In one or more embodiments, it is shown in FIG. 3 that the thin-film encapsulation layer 300 includes a first inorganic encapsulation layer 310, an organic encapsulation layer 320 on the first inorganic encapsulation layer 310, and a second inorganic encapsulation layer 330 on the organic encapsulation layer 320.

The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride and may be deposited using chemical vapor deposition. The first and second inorganic encapsulation layers 310 and 330 may include a single layer or a multi-layer including the above materials. The organic encapsulation layer 320 may include a polymer-based material. The polymer-based material may include an acryl-based resin, an epoxy-based resin, polyimide, and/or polyethylene. In one or more embodiments, the organic encapsulation layer 320 may include acrylate.

The first inorganic encapsulation layer 310 may be arranged on the auxiliary electrode layer 250 and (substantially) continuously formed to entirely overlap or cover (e.g., overlaps or covers an entirety of) the auxiliary electrode layer 250. The first inorganic encapsulation layer 310 having relatively excellent or suitable step coverage may cover each of the lateral surfaces defining the first to third openings OP1, OP2, and OP3 of the pixel-defining layer 120. In one or more embodiments, the organic encapsulation layer 320 may be arranged on the first inorganic encapsulation layer 310 and may fill at least a portion of each of the first to third openings OP1, OP2, and OP3 of the pixel-defining layer 120. The second inorganic encapsulation layer 330 is arranged on the organic encapsulation layer 320.

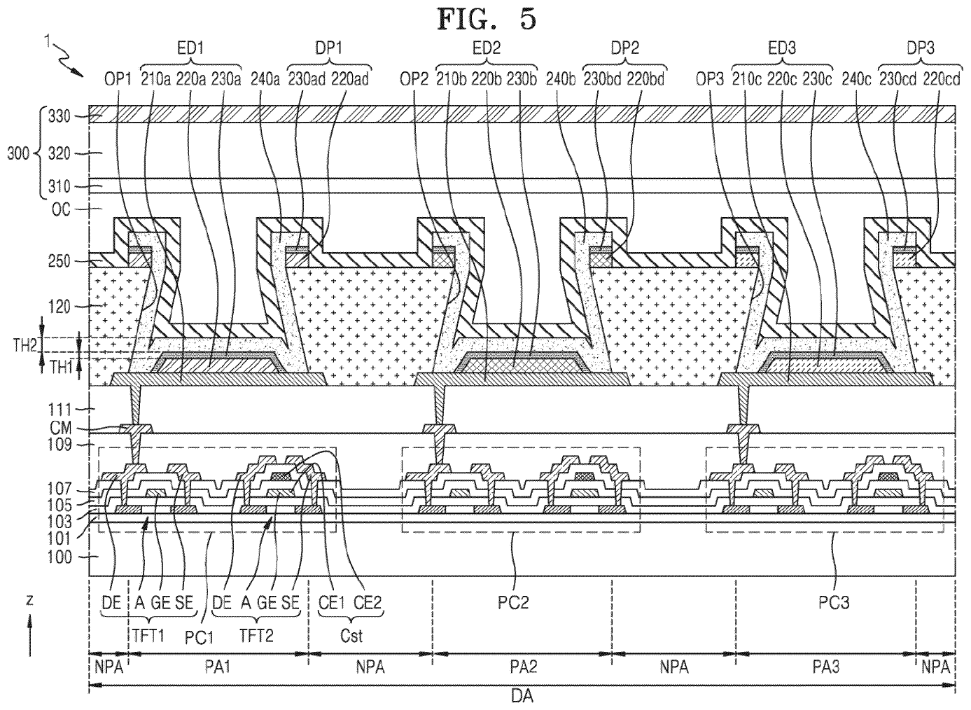

FIG. 5 is a schematic cross-sectional view of the display apparatus 1 according to one or more embodiments of the present disclosure. FIG. 5 is a modified embodiment of the embodiments described with reference to FIGS. 3 and 4, and repeated descriptions may be omitted and modified portions are mainly described.

Referring to FIG. 5, the display apparatus 1 may further include an overcoat layer OC. The overcoat layer OC may be arranged between the first to third light-emitting elements ED1, ED2, and ED3 and the thin-film encapsulation layer 300. In one or more embodiments, the overcoat layer OC may be arranged on the auxiliary electrode layer 250 to provide a flat upper surface. The overcoat layer OC may be arranged to cover the first to third light-emitting elements ED1, ED2, and ED3. The overcoat layer OC may be arranged to fill at least a portion of each of the first to third openings OP1, OP2, and OP3 of the pixel-defining layer 120. The overcoat layer OC may be configured to planarize the surface on which the thin-film encapsulation layer 300 is arranged.

The thin-film encapsulation layer 300 may be arranged on the overcoat layer OC. In one or more embodiments, the first inorganic encapsulation layer 310, the organic encapsulation layer 320, and the second inorganic encapsulation layer 330 may be sequentially stacked on the overcoat layer OC. In one or more embodiments, because the overcoat layer OC planarizes the surface on which the thin-film encapsulation layer 300 is arranged, the flatness by the thin-film encapsulation layer 300 may relatively increase.

The overcoat layer OC may include an organic material. As an example, the overcoat layer OC may include an organic material such as a general-purpose polymer such as polymethylmethacrylate (PMMA) and/or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a (e.g., any suitable) blend thereof. The overcoat layer OC may include a composite stack body including an inorganic layer including an inorganic material and an organic layer including an organic material. The inorganic layer may include an inorganic material such as SiO₂, SiNₓ, SiON, Al₂O₃, TiO₂, Ta₂O₅, HfO₂, ZrO₂, BST, and/or PZT.

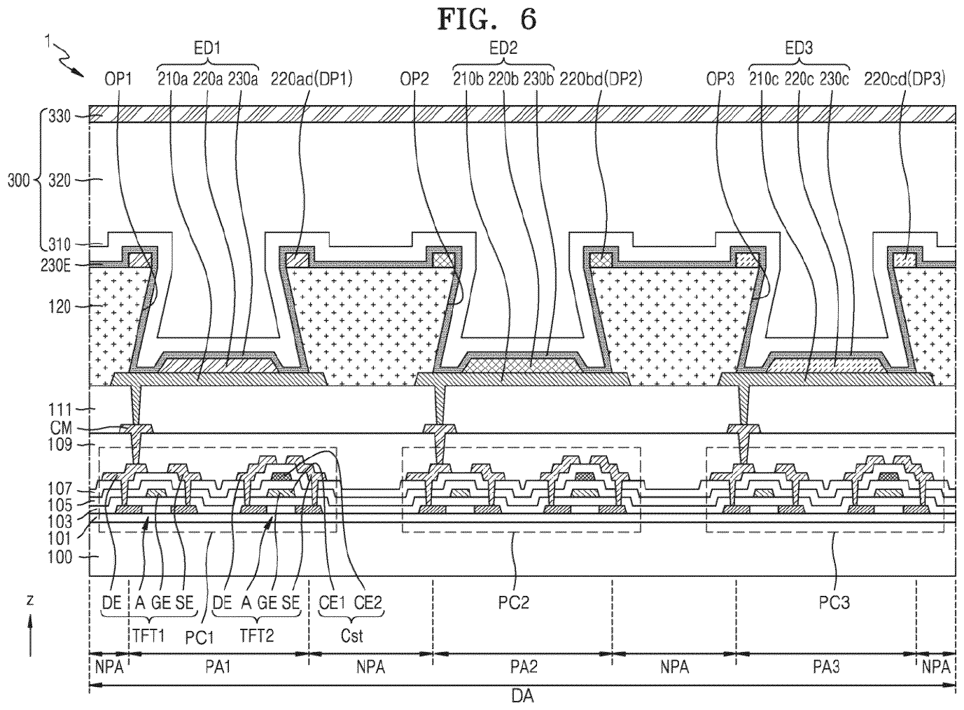

FIG. 6 is a schematic cross-sectional view of a display apparatus according to one or more embodiments of the present disclosure. FIG. 6 is a modified embodiment of the embodiments described with reference to FIGS. 3 and 4, and repeated descriptions may be omitted and modified portions are mainly described.

Referring to FIG. 6, the first opposite electrode 230a of the first light-emitting element ED1, the second opposite electrode 230b of the second light-emitting element ED2, and the third opposite electrode 230c of the third light-emitting element ED3 may be one opposite electrode 230E integrally provided. For example, the first opposite electrode 230a of the first light-emitting element ED1, the second opposite electrode 230b of the second light-emitting element ED2, and the third opposite electrode 230c of the third light-emitting element ED3 may be electrically connected to each other.

The opposite electrode 230E may be integrally formed over the plurality of pixels. For example, the opposite electrode 230E may be arranged over the first pixel area PA1, the second pixel area PA2, the third pixel area PA3, and the entire non-pixel area NPA. The opposite electrode 230E may overlap the intermediate layer 220a, the second intermediate layer 220b, and the third intermediate layer 220c and overlap the pixel-defining layer 120. As an example, the opposite electrode 230E may overlap the pixel-defining layer 120 and overlap the first to third openings OP1, OP2, and OP3 of the pixel-defining layer 120. As an example, the opposite electrode 230E may overlap the entire upper surface of the pixel-defining layer 120.

The opposite electrode 230E may cover at least a portion of the lateral surface defining the first opening OP1 of the pixel-defining layer 120, at least a portion of the lateral surface defining the second opening OP2, and at least a portion of the lateral surface defining the third opening OP3. The opposite electrode 230E may be in contact with at least a portion of the lateral surface defining the first opening OP1 of the pixel-defining layer 120, at least a portion of the lateral surface defining the second opening OP2, and at least a portion of the lateral surface defining the third opening OP3. The opposite electrode 230E may be continuously formed to overlap (or cover) the upper surface and lateral surface of each of the first intermediate layer 220a, the second intermediate layer 220b, the third intermediate layer 220c, and the upper surface and lateral surface of the pixel-defining layer 120.

In one or more embodiments, each of the first to third dummy patterns DP1, DP2, and DP3 may include a dummy intermediate layer and may not include (e.g., may exclude) a dummy opposite electrode. For example, the first dummy pattern DP1 may include the first dummy intermediate layer 220ad, the second dummy pattern DP2 may include the second dummy intermediate layer 220bd, and the third dummy pattern DP3 may include the third dummy intermediate layer 220cd.

The opposite electrode 230E may be arranged on each of the first to third dummy patterns DP1, DP2, and DP3. The opposite electrode 230E may be in contact with each of the first to third dummy patterns DP1, DP2, and DP3. The opposite electrode 230E may cover the inner surface, the upper surface, and the outer surface of the first dummy pattern DP1, may cover the inner surface, the upper surface, and the outer surface of the second dummy pattern DP2, and may cover the inner surface, the upper surface, and the outer surface of the third dummy pattern DP3. As an example, the opposite electrode 230E may cover the inner surface, the upper surface, and the outer surface of the first dummy intermediate layer 220ad, may cover the inner surface, the upper surface, and the outer surface of the second dummy intermediate layer 220bd, and may cover the inner surface, the upper surface, and the outer surface of the third dummy intermediate layer 220cd.

As shown in FIG. 3, it is shown in FIG. 6 that the first inorganic encapsulation layer 310 is arranged to cover each of the lateral surfaces defining the first to third openings OP1, OP2, and OP3 of the pixel-defining layer 120, and the organic encapsulation layer 320 fills at least a portion of each of the first to third openings OP1, OP2, and OP3. However, the present disclosure is not limited thereto. As an example, like the embodiments described with reference to FIG. 5, one or more embodiments described with reference to FIG. 6 may further include the overcoat layer OC arranged between first to third light-emitting elements ED1, ED2, and ED3, and the thin-film encapsulation layer 300.

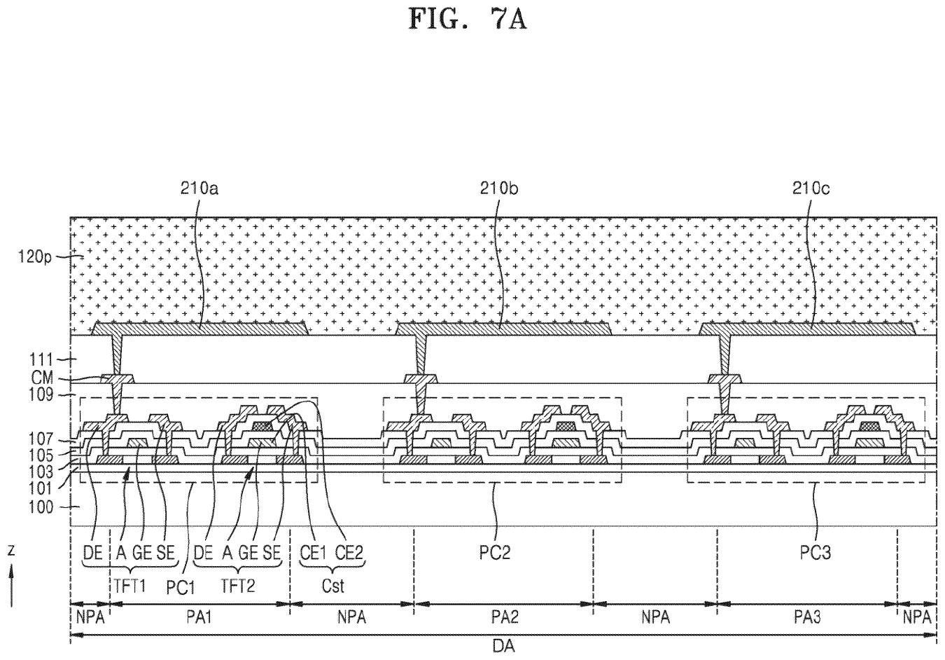

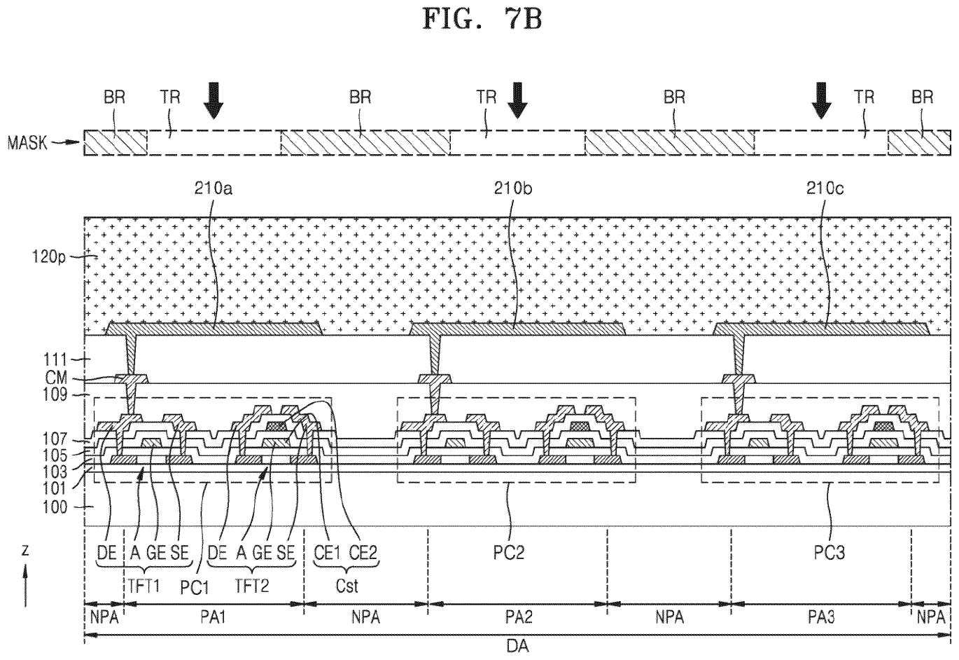

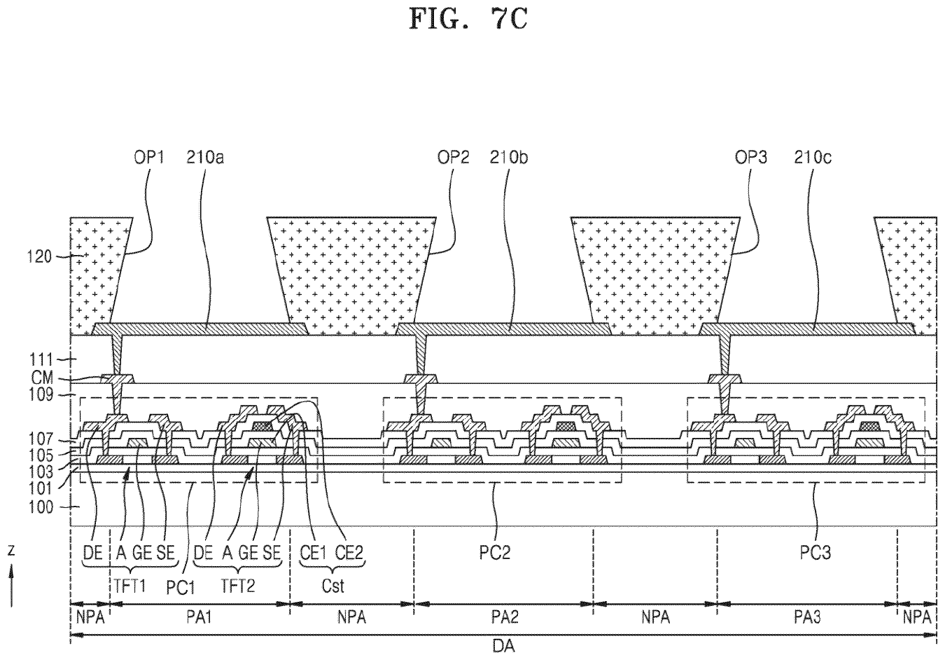

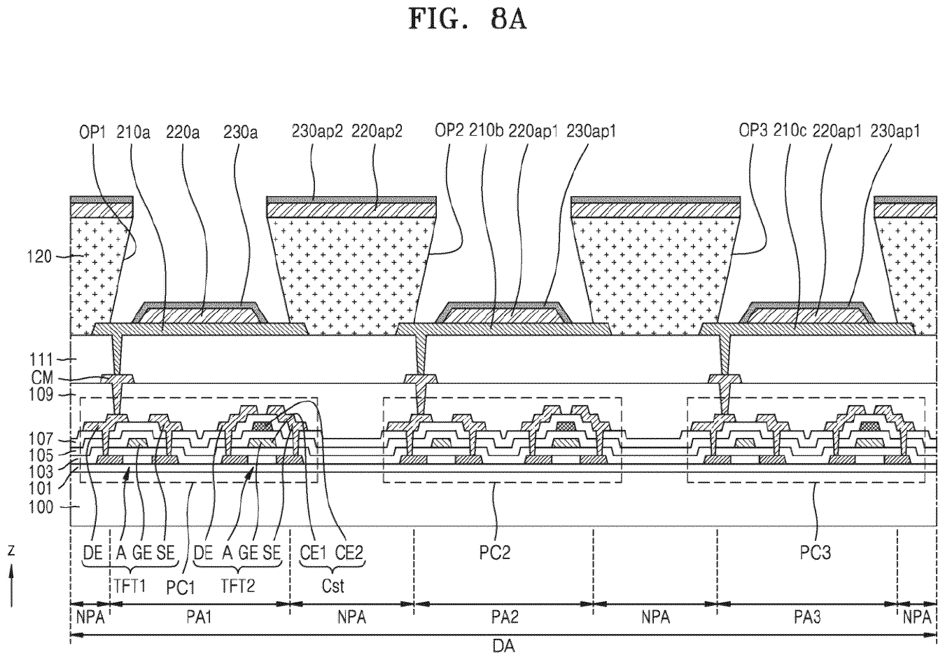

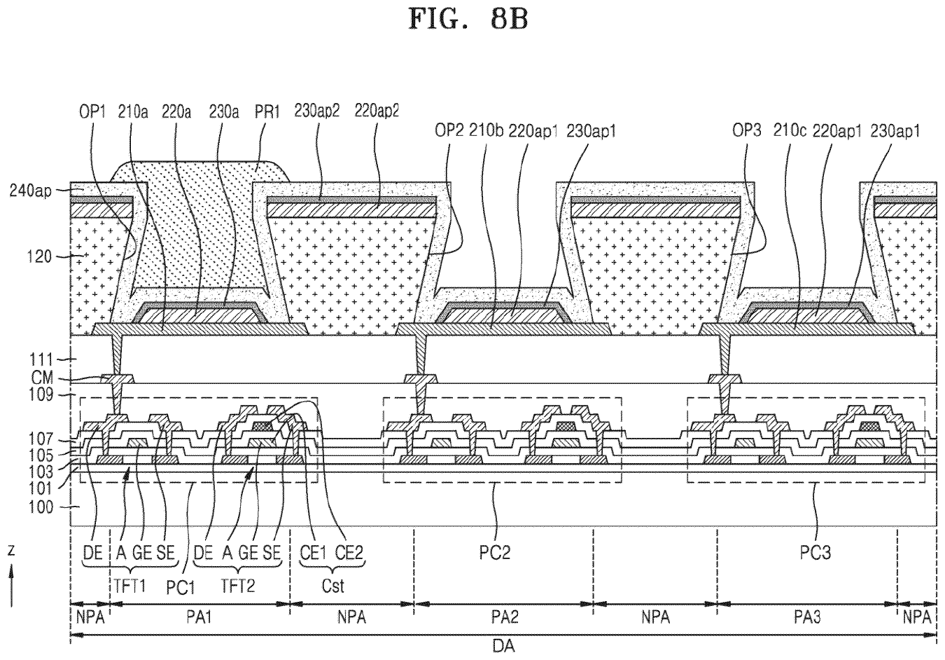

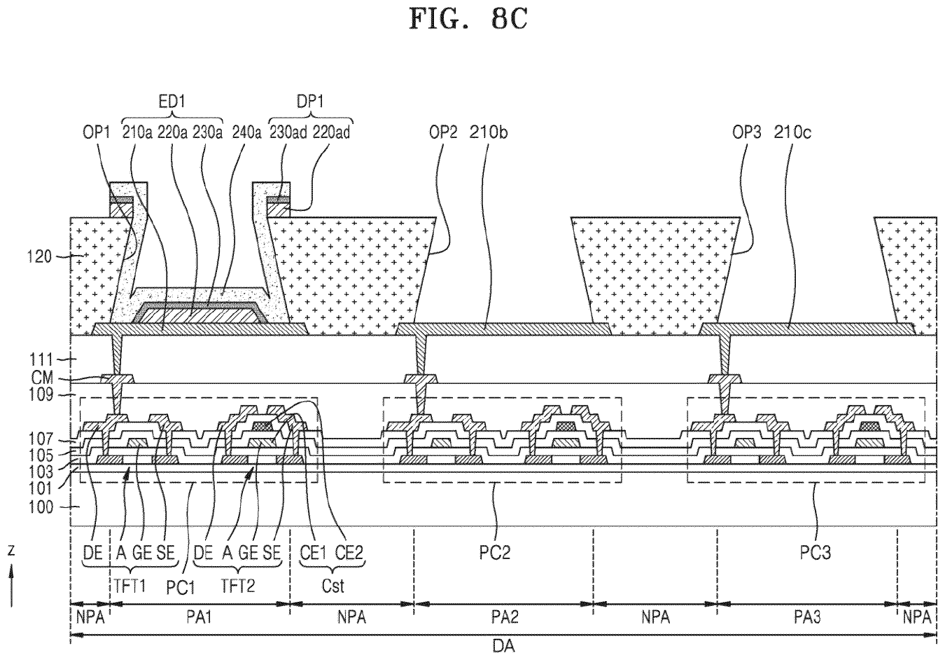

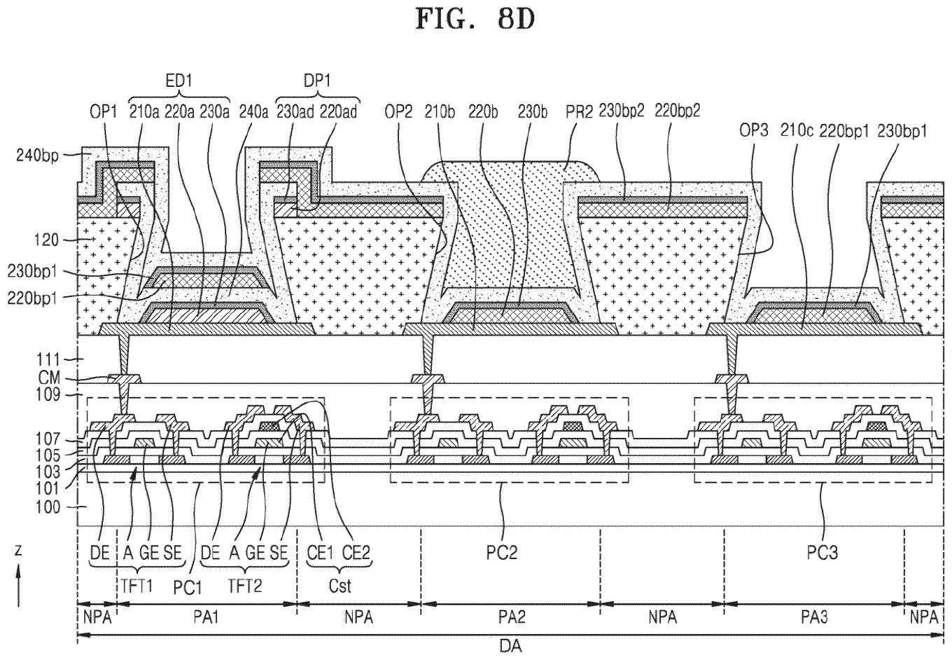

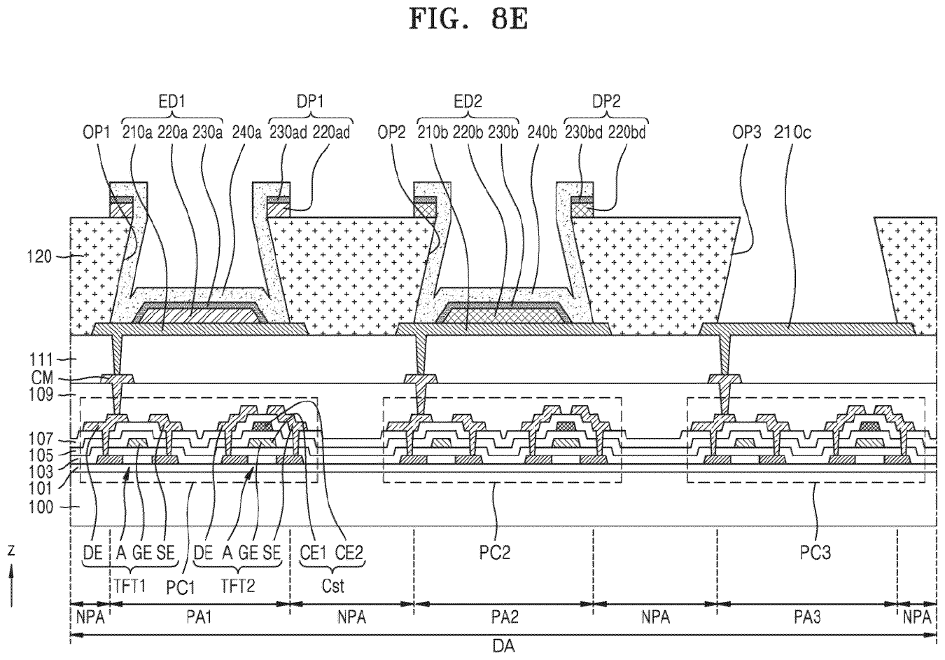

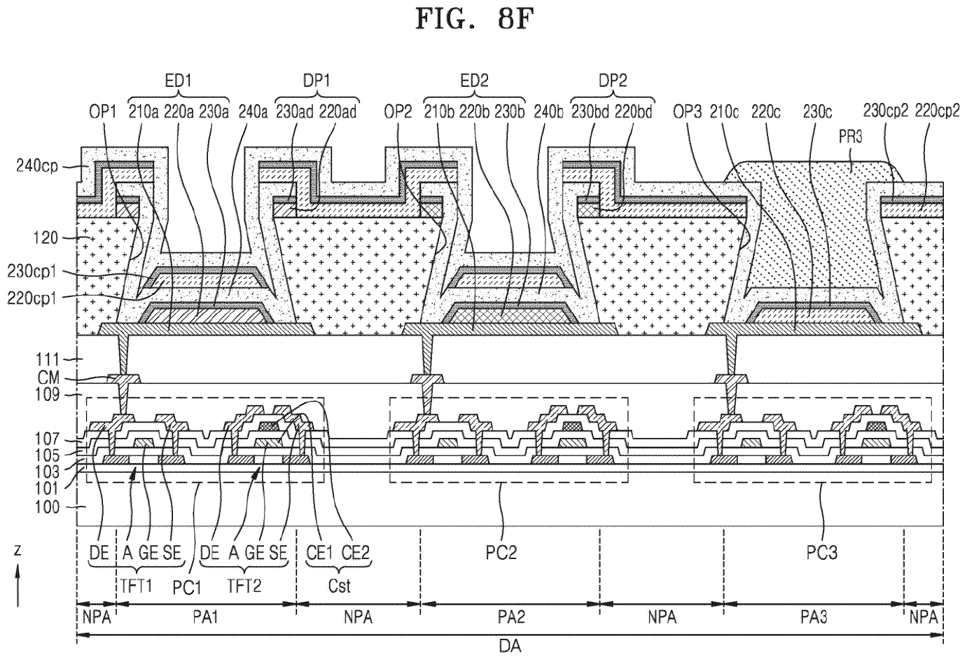

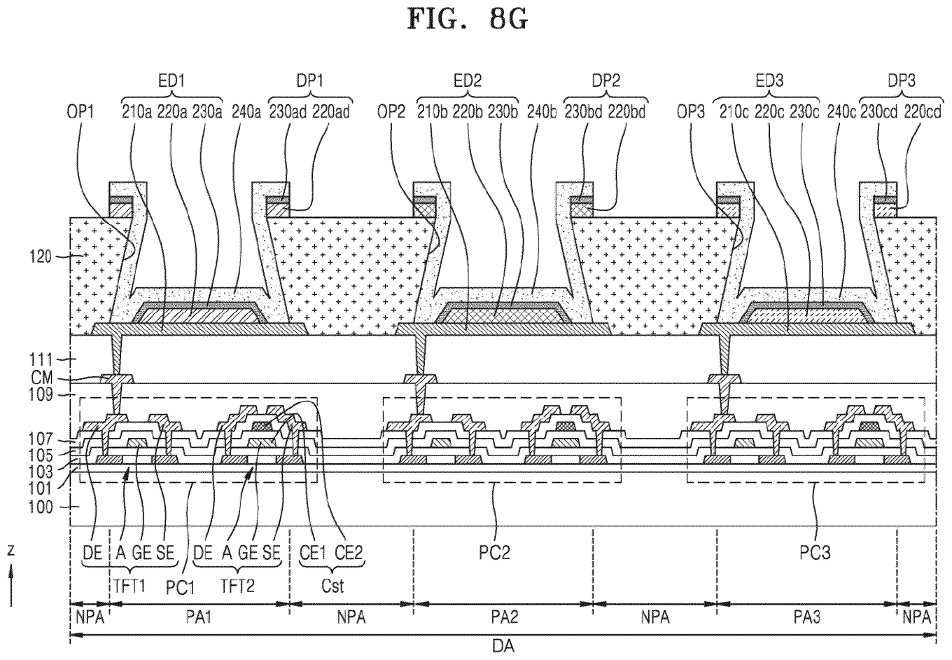

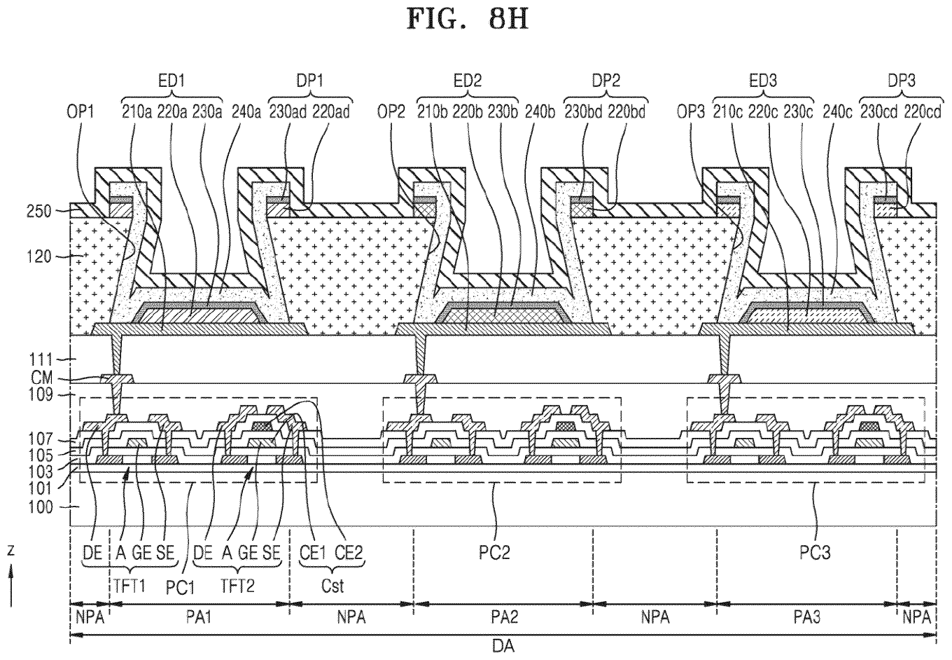

FIGS. 7A to 7C are schematic cross-sectional views showing states corresponding to a process of manufacturing a display apparatus according to one or more embodiments of the present disclosure. FIGS. 8A to 8H are schematic cross-sectional views showing states corresponding to a process of manufacturing a display apparatus according to one or more embodiments of the present disclosure. FIGS. 7A to 8H show each manufacturing process in a cross-section corresponding to the cross-section of the display apparatus 1 described with reference to FIG. 3, according to one or more embodiments of the present disclosure.

FIGS. 7A to 7C show, for each operation, a process of forming the pixel-defining layer 120 of a reverse taper shape on the first to third pixel electrodes 210a, 210b, and 210c.

Referring to FIG. 7A, the first to third sub-pixel circuits PC1, PC2, and PC3 may be formed over the substrate 100. The buffer layer 101 may be formed on the substrate 100 before the first to third pixel circuits PC1, PC2, and PC3 are formed. In one or more embodiments, each of the first to third pixel circuits PC1, PC2, and PC3 may include the first thin-film transistor TFT1, the second thin-film transistor TFT2, and the storage capacitor Cst.

In one or more embodiments, the first thin-film transistor TFT1, the second thin-film transistor TFT2, and the storage capacitor Cst may be formed on the buffer layer 101. Each of the first thin-film transistor TFT1 and the second thin-film transistor TFT2 may include the semiconductor layer A on the buffer layer 101, and the gate electrode GE overlapping the channel region of the semiconductor layer A. The first gate insulating layer 103 may be arranged between the semiconductor layer A and the gate electrode GE.

The first interlayer insulating layer 105 may be formed on the gate electrode GE. The upper electrode CE2 may be formed on the first interlayer insulating layer 105. The second interlayer insulating layer 107 may be formed on the upper electrode CE2. The source electrode SE and the drain electrode DE may be formed on the second interlayer insulating layer 107. The source electrode SE and the drain electrode DE may be electrically connected to the semiconductor layer A through a contact hole passing through the second interlayer insulating layer 107, for example, a contact hole passing through the first interlayer insulating layer 105, the second interlayer insulating layer 107, and the first gate insulating layer 103.

The first organic insulating layer 109 may be formed on the first and second thin-film transistors TFT1 and TFT2, and the connection metal CM may be formed on the first organic insulating layer 109. The connection metal CM may be electrically connected to the first and second thin-film transistors TFT1 and TFT2 through a contact hole passing through the first organic insulating layer 109. The second organic insulating layer 111 may be formed on the connection metal CM.

The first to third pixel electrodes 210a, 210b, and 210c may be formed on the second organic insulating layer 111 to be apart from each other. Because the first to third pixel electrodes 210a, 210b, and 210c are formed in substantially the same process, the first to third pixel electrodes 210a, 210b, and 210c may include substantially the same material. As an example, the first to third pixel electrodes 210a, 210b, and 210c may be formed by forming a conductive layer on the second organic insulating layer 111 and then patterning the conductive layer using a mask process.

The first to third pixel electrode 210a, 210b, and 210c may include metal and/or conductive oxide. As an example, the first to third pixel electrodes 210a, 210b, and 210c may include a reflective layer including Ag, Mg, Al, Pt, Pd, Au, Ni, Nd, Ir, Cr, and/or compounds thereof. The first to third pixel electrode 210a, 210b, and 210c may further include a transparent or semi-transparent conductive layer under and/or on the reflective layer. The transparent or semi-transparent conductive layer may include, for example, at least one of indium tin oxide (ITO), indium zinc oxide (IZO), zinc oxide (ZnO), indium oxide (In₂O₃), indium gallium oxide (IGO), and/or aluminum zinc oxide (AZO).

A preliminary pixel-defining layer 120p may be stacked on the first to third pixel electrodes 210a, 210b, and 210c. The preliminary pixel-defining layer 120p may include, for example, an organic material such as photosensitive polyimide (PSPI), polyimide, polyamide, acrylic resin, benzocyclobutene, and/or phenolic resin. In one or more embodiments, the preliminary pixel-defining layer 120p may include a photosensitive organic material. In one or more embodiments, the preliminary pixel-defining layer 120p may include a negative type or kind photosensitive organic material.

Referring to FIG. 7B, a mask MASK may be placed over the preliminary pixel definition layer 120p, and an exposure process may be performed. The mask MASK may include a light-blocking portion BR configured to block most of light or reduce the amount of light and a transmissive portion TR configured to transmit most of light. The transmissive portion TR of the mask MASK may overlap each of the first to third pixel electrodes 210a, 210b, and 210c. For example, light may be irradiated to regions respectively overlapping the first to third pixel electrodes 210a, 210b, and 210c.

Referring to FIG. 7C, the pixel-defining layer 120 including the first opening OP1 exposing a portion of the first pixel electrode 210a, the second opening OP2 exposing a portion of the second pixel electrode 210b, and the third opening OP3 exposing a portion of the third pixel electrode 210c may be formed by removing a portion of the preliminary pixel-defining layer 120p (see FIG. 7B). As described with reference to FIG. 7B, the pixel-defining layer 120 having the reverse taper structure may be formed by developing the preliminary pixel-defining layer 120p to which light is irradiated (e.g., by irradiating the preliminary pixel-defining layer 120p). In one or more embodiments, because the preliminary pixel-defining layer 120p includes a negative type or kind photosensitive organic material, and a portion of the preliminary pixel-defining layer 120p corresponding to a portion to which light is irradiated is removed to form the pixel-defining layer 120, the pixel-defining layer 120 may have the reverse taper structure in which the width of the upper surface is greater than the width of the lower surface.

Although it is shown in FIG. 7C that the pixel-defining layer 120 is a trapezoidal shape, this is an example and the present disclosure is not limited thereto. In one or more embodiments, the pixel-defining layer 120 may have a reverse taper shape, and the corners of the upper surface thereof may be rounded. In one or more embodiments, the pixel-defining layer 120 may have an undercut structure. As an example, the pixel-defining layer 120 may form an undercut structure in which the upper region of the pixel-defining layer 120 protrudes more than the lower region. In one or more embodiments, although the slope of the lateral surface of the pixel-defining layer 120 is constant, the present disclosure is not limited thereto. As another example, the pixel-defining layer 120 may have an undercut structure including regions with different side slopes.

Because, in the display apparatus 1 according to one or more embodiments, the pixel-defining layer 120 of the reverse taper structure is formed by the photo process, costs and/or manufacturing time in forming the pixel-defining layer 120 may be reduced. In addition, because the display apparatus 1 according to one or more embodiments includes the pixel-defining layer 120 having the reverse taper shape, the number of masks used in the subsequent process (e.g., a process of forming the intermediate layer) is reduced, and thus, costs and/or manufacturing time may be reduced.

Referring to FIG. 8A, the first intermediate layer 220a arranged on the first pixel electrode 210a in the first opening OP1 of the pixel-defining layer 120, a first temporary intermediate layer 220ap1 arranged on each of the second pixel electrode 210b in the second opening OP2 of the pixel-defining layer 120 and the third pixel electrode 210c in the third opening OP3 of the pixel-defining layer 120, and a first preliminary dummy intermediate layer 220ap2 arranged on the upper surface of the pixel-defining layer 120 may be formed. Next, the first opposite electrode 230a arranged on the first intermediate layer 220a in the first opening OP1 of the pixel-defining layer 120, a first temporary opposite electrode 230ap1 arranged on each of the first temporary intermediate layer 220ap1 in the second opening OP2 of the pixel-defining layer 120 and the first temporary intermediate layer 220ap1 in the third opening OP3 of the pixel-defining layer 120, and a first preliminary dummy opposite electrode 230ap2 on the first preliminary dummy intermediate layer 220ap2 may be formed.

In one or more embodiments, the first intermediate layer 220a and the first opposite electrode 230a may each be formed by deposition methods such as thermal deposition.

Because the first intermediate layer 220a is deposited without a separate mask, a deposition material for forming the first intermediate layer 220a may form the first intermediate layer 220a in the first opening OP1 of the pixel-defining layer 120. The first temporary intermediate layer 220ap1 may be formed in each of the second opening OP2 and the third opening OP3 of the pixel-defining layer 120, and the first preliminary dummy intermediate layer 220ap2 may be formed on the upper surface of the pixel-defining layer 120. For example, the first intermediate layer 220a, the first temporary intermediate layer 220ap1, and the first preliminary dummy intermediate layer 220ap2 may be concurrently (e.g., simultaneously) formed. In such embodiments, because the pixel-defining layer 120 has the reverse taper shape, the first intermediate layer 220a and the first preliminary dummy intermediate layer 220ap2 may be separated and apart from each other. In one or more embodiments, the first temporary intermediate layer 220ap1 and the first preliminary dummy intermediate layer 220ap2 may be separated and apart from each other.

The first intermediate layer 220a may include the emission layer 222 as shown in FIG. 4. The first intermediate layer 220a may include a common layer arranged between the first pixel electrode 210a and the emission layer 222 and/or between the emission layer 222 and the first opposite electrode 230a. The first intermediate layer 220a and the first preliminary dummy intermediate layer 220ap2 may include the same material and/or the same number of sub-layers (e.g., a first common layer, an emission layer, and a second common layer).

Because the first opposite electrode 230a is deposited without a separate mask, a deposition material for forming the first opposite electrode 230a may form the first opposite electrode 230a in the first opening OP1 of the pixel-defining layer 120. The first temporary opposite electrode 230ap1 may be formed in each of the second opening OP2 and the third opening OP3 of the pixel-defining layer 120, and the first preliminary dummy opposite electrode 230ap2 may be formed on the first preliminary dummy intermediate layer 220ap2. For example, the first opposite electrode 230a, the first temporary opposite electrode 230ap1, and the first preliminary dummy opposite electrode 230ap2 may be concurrently (e.g., simultaneously) formed. In such embodiments, because the pixel-defining layer 120 has the reverse taper shape, the first opposite electrode 230a and the first preliminary dummy opposite electrode 230ap2 may be separated and apart from each other. In one or more embodiments, the first temporary opposite electrode 230ap1 and the first preliminary dummy opposite electrode 230ap2 may be separated and apart from each other.

Referring to FIG. 8B, the first preliminary auxiliary electrode pattern 240ap may be formed to cover the upper surface of the first opposite electrode 230a, the lateral surface defining the first opening OP1 of the pixel-defining layer 120, and the upper surface of the first preliminary dummy opposite electrode 230ap2. The first preliminary auxiliary electrode pattern 240ap may be formed to entirely cover (e.g., cover an entirety of) the first opposite electrode 230a, the first temporary opposite electrode 230ap1, and the first preliminary dummy opposite electrode 230ap2.

In one or more embodiments, the first preliminary auxiliary electrode pattern 240ap may be formed to cover each of the lateral surface defining the first opening OP1, the lateral surface defining the second opening OP2, and the lateral surface defining the third opening OP3 of the pixel-defining layer 120. As an example, the first preliminary auxiliary electrode pattern 240ap may be arranged along each of the profile of the lateral surface defining the first opening OP1, the profile of the lateral surface defining the second opening OP2, and the profile of the lateral surface defining the third opening OP3 of the pixel-defining layer 120. As an example, the first preliminary auxiliary electrode pattern 240ap may be in contact with each of the lateral surface defining the first opening OP1, the lateral surface defining the second opening OP2, and the lateral surface defining the third opening OP3 of the pixel-defining layer 120. As an example, the first preliminary auxiliary electrode pattern 240ap may be formed to be arranged along the lateral surface of the pixel-defining layer 120 of the reverse taper shape by performing a process in which an incident angle of particles may be adjusted, such as a damage free sputter (DFS) process, an oblique angle deposition (OAD) process, and/or the like.

The thickness of the first preliminary auxiliary electrode pattern 240ap may be formed greater than (e.g., may be thicker than) the thickness of the first opposite electrode 230a. Because the thickness of the first preliminary auxiliary electrode pattern 240ap is formed relatively greater, a damage to the first intermediate layer 220a arranged under the first preliminary auxiliary electrode pattern 240ap may be prevented or reduced during the subsequent process (e.g., an etching process, a photoresist pattern-removing process, and/or the like).

Next, a first photoresist pattern PR1 overlapping the first opening OP1 of the pixel-defining layer 120 may be formed on the first preliminary auxiliary electrode pattern 240ap. The first photoresist pattern PR1 may overlap the first pixel electrode 210a, a first intermediate layer 220a, and a first opposite electrode 230a. The first photoresist pattern PR1 may overlap a portion of the first preliminary dummy intermediate layer 220ap2, a portion of the first preliminary dummy opposite electrode 230ap2, and a portion of the first preliminary auxiliary electrode pattern 240ap.

Referring to FIG. 8B and FIG. 8C, by using the first photoresist pattern PR1 as a mask, the first dummy pattern DP1 including the first dummy intermediate layer 220ad and the first dummy opposite electrode 230ad may be formed by removing the remaining portion of the first preliminary dummy intermediate layer 220ap2 and the remaining portion of the first preliminary dummy opposite electrode 230ap2 that do not overlap the first photoresist pattern PR1, and the first auxiliary electrode pattern 240a covering the upper surface of the first opposite electrode 230a, the lateral surface defining the first opening OP1 of the pixel-defining layer 120, and the upper surface of the first dummy pattern DP1 may be formed by removing the remaining portion of the first preliminary auxiliary electrode pattern 240ap. The removing of a portion of the first preliminary dummy intermediate layer 220ap2, a portion of the first preliminary dummy opposite electrode 230ap2, and a portion of the first preliminary auxiliary electrode pattern 240ap using the first photoresist pattern PR1 as a mask may be, for example, a wet etching process or a dry etching process. Accordingly, the first auxiliary electrode pattern 240a may have an island pattern shape in a plan view. In such embodiments, the first temporary intermediate layer 220ap1 and the first temporary opposite electrode 230ap1 may be also removed together using the first photoresist pattern PR1 as a mask.

Similar to the description made with reference to FIG. 8A, referring to FIG. 8D, the second intermediate layer 220b arranged on the second pixel electrode 210b in the second opening OP2 of the pixel-defining layer 120, a second temporary intermediate layer 220bp1 arranged on each of the first auxiliary electrode pattern 240a in the first opening OP1 of the pixel-defining layer 120 and the third pixel electrode 210c in the third opening OP3 of the pixel-defining layer 120, and a second preliminary dummy intermediate layer 220bp2 arranged on the upper surface of the pixel-defining layer 120 may be formed. Next, the second opposite electrode 230b arranged on the second intermediate layer 220b in the second opening OP2 of the pixel-defining layer 120, a second temporary opposite electrode 230bp1 arranged on each of the second temporary intermediate layer 220bp1 in the first opening OP1 of the pixel-defining layer 120 and the second temporary intermediate layer 220bp1 in the third opening OP3 of the pixel-defining layer 120, and a second preliminary dummy opposite electrode 230bp2 on the second preliminary dummy intermediate layer 220bp2 may be formed.

Similar to the first intermediate layer 220a, the second intermediate layer 220b may include an emission layer and include the emission layer configured to emit light of a different color from the color of light emitted from the first intermediate layer 220a. The second intermediate layer 220b may include a common layer arranged between the second pixel electrode 210b and the emission layer and/or between the emission layer and the second opposite electrode 230b. The second intermediate layer 220b and the second preliminary dummy intermediate layer 220bp2 may include substantially the same material and/or substantially the same number of sub-layers (e.g., the first common layer, the emission layer, and the second common layer).

Similar to the first intermediate layer 220a, the second intermediate layer 220b may be separated and apart from the second preliminary dummy intermediate layer 220bp2. Similar to the first opposite electrode 230a, the second opposite electrode 230b may be separated and apart from the second preliminary dummy opposite electrode 230bp2.

Next, similar to the description made with reference to FIG. 8B, a second preliminary auxiliary electrode pattern 240bp may be formed to cover the upper surface of the second opposite electrode 230b, the lateral surface defining the second opening OP2 of the pixel-defining layer 120, and the upper surface of the second preliminary dummy opposite electrode 230bp2. The second preliminary auxiliary electrode pattern 240bp may be formed to entirely cover (e.g., cover an entirety of) the second opposite electrode 230b, the second temporary opposite electrode 230bp1, and the second preliminary dummy opposite electrode 230bp2.

In one or more embodiments, the second preliminary auxiliary electrode pattern 240bp may be formed to cover each of the lateral surface defining the first opening OP1, the lateral surface defining the second opening OP2, and the lateral surface defining the third opening OP3 of the pixel-defining layer 120. Because the description of forming of the second preliminary auxiliary electrode pattern 240bp is substantially the same as or similar to the forming of the first preliminary auxiliary electrode pattern 240ap described with reference to FIG. 8B, a detailed description thereof may be omitted.

The thickness of the second preliminary auxiliary electrode pattern 240bp may be formed greater than (e.g., may be thicker than) the thickness of the second opposite electrode 230b. Because the thickness of the second preliminary auxiliary electrode pattern 240bp is formed relatively greater, a damage to the second intermediate layer 220b arranged under the second preliminary auxiliary electrode pattern 240bp may be prevented or reduced during the subsequent process.

Next, a second photoresist pattern PR2 overlapping the second opening OP2 of the pixel-defining layer 120 may be formed on the second preliminary auxiliary electrode pattern 240bp. The second photoresist pattern PR2 may overlap the second pixel electrode 210b, the second intermediate layer 220b, and the second opposite electrode 230b. The second photoresist pattern PR2 may overlap a portion of the second preliminary dummy intermediate layer 220bp2, a portion of the second preliminary dummy opposite electrode 230bp2, and a portion of the second preliminary auxiliary electrode pattern 240bp. The second photoresist pattern PR2 may not overlap the first light-emitting element ED1, the first auxiliary electrode pattern 240a, and the first dummy pattern DP1.

Referring to FIG. 8D and FIG. 8E, by using the second photoresist pattern PR2 as a mask, the second dummy pattern DP2 including the second dummy intermediate layer 220bd and the second dummy opposite electrode 230bd may be formed by removing the remaining portion of the second preliminary dummy intermediate layer 220bp2 and the remaining portion of the second preliminary dummy opposite electrode 230bp2 that do not overlap the second photoresist pattern PR2, and the second auxiliary electrode pattern 240b covering the upper surface of the second opposite electrode 230b, the lateral surface defining the second opening OP2 of the pixel-defining layer 120, and the upper surface of the second dummy pattern DP2 may be formed by removing the remaining portion of the second preliminary auxiliary electrode pattern 240bp. In such embodiments, the second temporary intermediate layer 220bp1 and the second temporary opposite electrode 230bp1 may be also removed together using the second photoresist pattern PR2 as a mask.

The second dummy pattern DP2 may be formed to be apart from the first dummy pattern DP1. The second auxiliary electrode pattern 240b may be apart from the first auxiliary electrode pattern 240a. The second auxiliary electrode pattern 240b may have an island pattern shape.

Similar to the description made with reference to FIGS. 8A and 8D, referring to FIG. 8F, the third intermediate layer 220c arranged on the third pixel electrode 210c in the third opening OP3 of the pixel-defining layer 120, a third temporary intermediate layer 220cp1 arranged on each of the first auxiliary electrode pattern 240a in the first opening OP1 of the pixel-defining layer 120 and the second auxiliary electrode pattern 240b in the second opening OP2 of the pixel-defining layer 120, and a third preliminary dummy intermediate layer 220cp2 arranged on the upper surface of the pixel-defining layer 120 may be formed. Next, the third opposite electrode 230c arranged on the third intermediate layer 220c in the third opening OP3 of the pixel-defining layer 120, a third temporary opposite electrode 230cp1 arranged on each of the third temporary intermediate layer 220cp1 in the first opening OP1 of the pixel-defining layer 120 and the third temporary intermediate layer 220cp1 in the second opening OP2 of the pixel-defining layer 120, and a third preliminary dummy opposite electrode 230cp2 on the third preliminary dummy intermediate layer 220cp2 may be formed.

Similar to the first intermediate layer 220a and the second intermediate layer 220b, the third intermediate layer 220c may include an emission layer and include the emission layer configured to emit light of a different color from the color of light emitted from each of the first intermediate layer 220a and the second intermediate layer 220b. The third intermediate layer 220c may include a common layer arranged between the third pixel electrode 210c and the emission layer and/or between the emission layer and the third opposite electrode 230c. The third intermediate layer 220c and the third preliminary dummy intermediate layer 220cp2 may include substantially the same material and/or substantially the same number of sub-layers (e.g., the first common layer, the emission layer, and the second common layer).

Similar to the first intermediate layer 220a, the third intermediate layer 220c may be separated and apart from the third preliminary dummy intermediate layer 220cp2. Similar to the first opposite electrode 230a, the third opposite electrode 230c may be separated and apart from the third preliminary dummy opposite electrode 230cp2.

Next, similar to the description made with reference to FIGS. 8B and 8D, a third preliminary auxiliary electrode pattern 240cp may be formed to cover the upper surface of the third opposite electrode 230c, the lateral surface defining the third opening OP3 of the pixel-defining layer 120, and the upper surface of the third preliminary dummy opposite electrode 230cp2. The third preliminary auxiliary electrode pattern 240cp may be formed to entirely cover (e.g., cover an entirety of) the third opposite electrode 230c, the third temporary opposite electrode 230cp1, and the third preliminary dummy opposite electrode 230cp2.

In one or more embodiments, the third preliminary auxiliary electrode pattern 240cp may be formed to cover each of the lateral surface defining the first opening OP1, the lateral surface defining the second opening OP2, and the lateral surface defining the third opening OP3 of the pixel-defining layer 120. Because the description of forming of the third preliminary auxiliary electrode pattern 240cp is substantially the same as or similar to the forming of the first preliminary auxiliary electrode pattern 240ap described with reference to FIG. 8B, a detailed description thereof may be omitted.

The thickness of the third preliminary auxiliary electrode pattern 240cp may be formed greater than (e.g., may be thicker than) the thickness of the third opposite electrode 230c. Because the thickness of the third preliminary auxiliary electrode pattern 240cp is formed relatively greater, a damage to the third intermediate layer 220c arranged under the third preliminary auxiliary electrode pattern 240cp may be prevented or reduced during the subsequent process.

Next, a third photoresist pattern PR3 overlapping the third opening OP3 of the pixel-defining layer 120 may be formed on the third preliminary auxiliary electrode pattern 240cp. The third photoresist pattern PR3 may overlap the third pixel electrode 210c, the third intermediate layer 220c, and the third opposite electrode 230c. The third photoresist pattern PR3 may overlap a portion of the third preliminary dummy intermediate layer 220cp2, a portion of the third preliminary dummy opposite electrode 230cp2, and a portion of the third preliminary auxiliary electrode pattern 240cp. The third photoresist pattern PR3 may not overlap the first light-emitting element ED1, the second light-emitting element ED2, the first auxiliary electrode pattern 240a, the second auxiliary electrode pattern 240b, the first dummy pattern DP1, and the second dummy pattern DP2.

Referring to FIG. 8G, by using the third photoresist pattern PR3 as a mask, the third dummy pattern DP3 including the third dummy intermediate layer 220cd and the third dummy opposite electrode 230cd may be formed by removing the remaining portion of the third preliminary dummy intermediate layer 220cp2 and the remaining portion of the third preliminary dummy opposite electrode 230cp2 that do not overlap the third photoresist pattern PR3, and the third auxiliary electrode pattern 240c covering the upper surface of the third opposite electrode 230c, the lateral surface defining the third opening OP3 of the pixel-defining layer 120, and the upper surface of the third dummy pattern DP3 may be formed by removing the remaining portion of the third preliminary auxiliary electrode pattern 240cp. In such embodiments, the third temporary intermediate layer 220cp1 and the third temporary opposite electrode 230cp1 may be also removed together using the third photoresist pattern PR3 as a mask.

The third dummy pattern DP3 may be formed to be apart from the first dummy pattern DP1 and the second dummy pattern DP2. The third auxiliary electrode pattern 240c may be formed to be apart from the first auxiliary electrode pattern 240a and the second auxiliary electrode pattern 240b. The third auxiliary electrode pattern 240c may have an island pattern shape.

Referring to FIG. 8H, the auxiliary electrode layer 250 may be integrally formed over the plurality of pixels. The auxiliary electrode layer 250 may overlap the first light-emitting element ED1, the second light-emitting element ED2, and the third light-emitting element ED3 and overlap the pixel-defining layer 120. As an example, the auxiliary electrode layer 250 may be formed to overlap the pixel-defining layer 120 and overlap the first to third openings OP1, OP2, and OP3 of the pixel-defining layer 120.

The auxiliary electrode layer 250 may be formed on the first auxiliary electrode pattern 240a, the second auxiliary electrode pattern 240b, the third auxiliary electrode pattern 240c, and the pixel-defining layer 120. The auxiliary electrode layer 250 may be formed to entirely overlap or cover (e.g., overlap or cover an entirety of) the first auxiliary electrode pattern 240a, the second auxiliary electrode pattern 240b, the third auxiliary electrode pattern 240c, and the pixel-defining layer 120. The auxiliary electrode layer 250 may cover at least a portion of lateral surfaces respectively defining the first to third openings OP1, OP2, and OP3 of the pixel-defining layer 120. The auxiliary electrode layer 250 may be (substantially) continuously formed to overlap (or cover) the upper surface and lateral surface of each of the first auxiliary electrode pattern 240a, the second auxiliary electrode pattern 240b, the third auxiliary electrode pattern 240c, and the upper surface and lateral surface of the pixel-defining layer 120.

In one or more embodiments, additionally referring to FIG. 3, the thin-film encapsulation layer 300 may be formed on the first to third light-emitting elements ED1, ED2, and ED3. In one or more embodiments, the thin-film encapsulation layer 300 may be formed to include at least one inorganic encapsulation layer and at least one organic encapsulation layer.

In one or more embodiments, additionally referring to FIG. 5, the overcoat layer OC may be formed on the first to third light-emitting elements ED1, ED2, and ED3, and the thin-film encapsulation layer 300 may be formed on the overcoat layer OC.

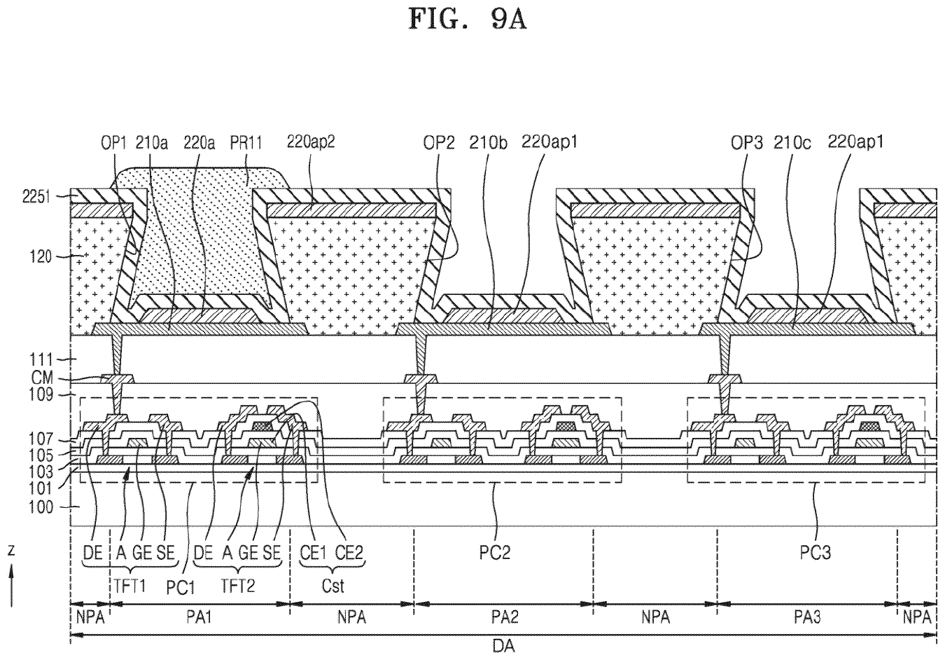

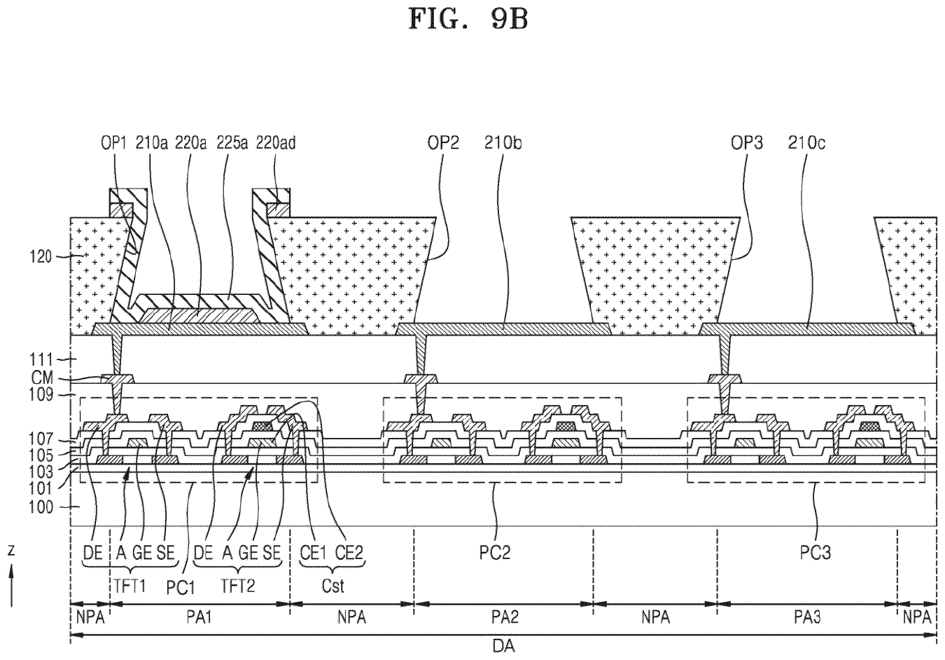

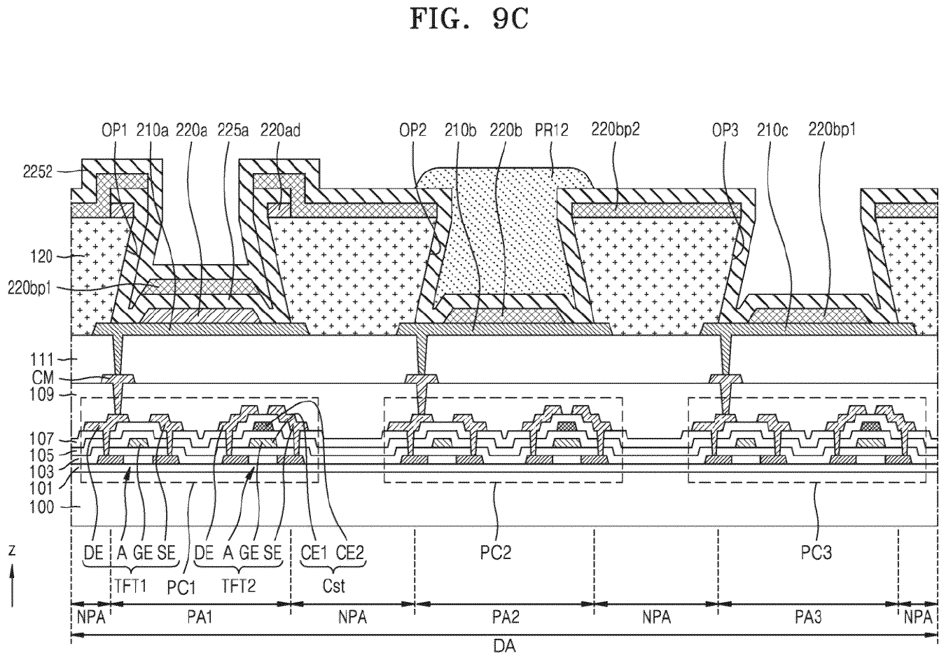

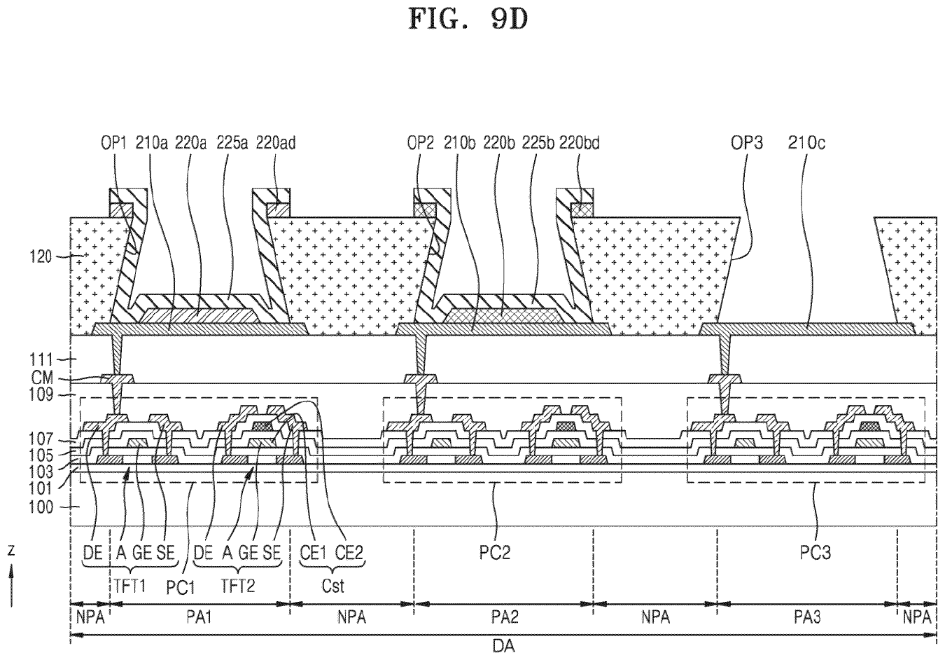

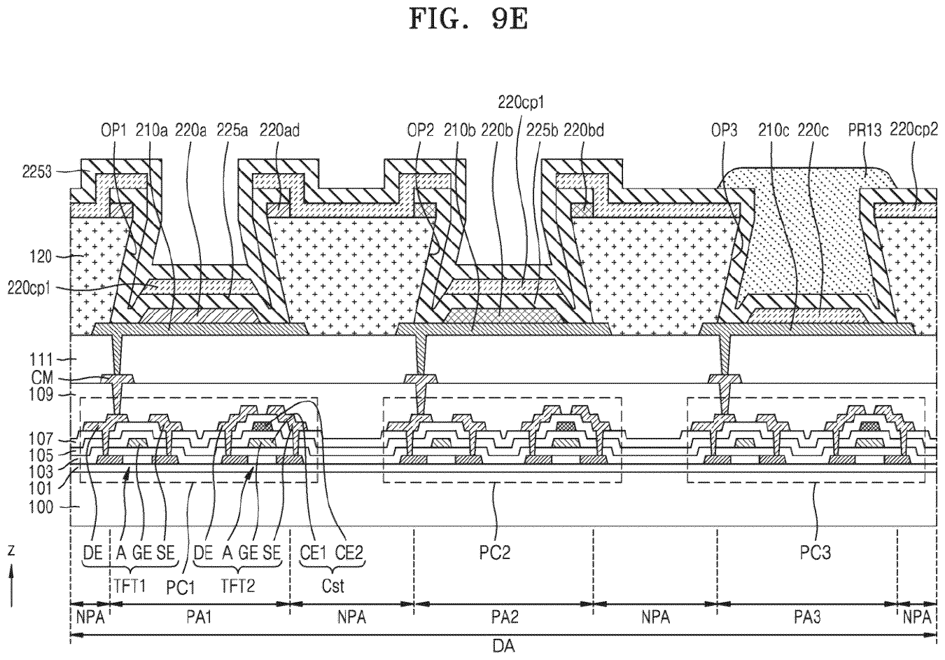

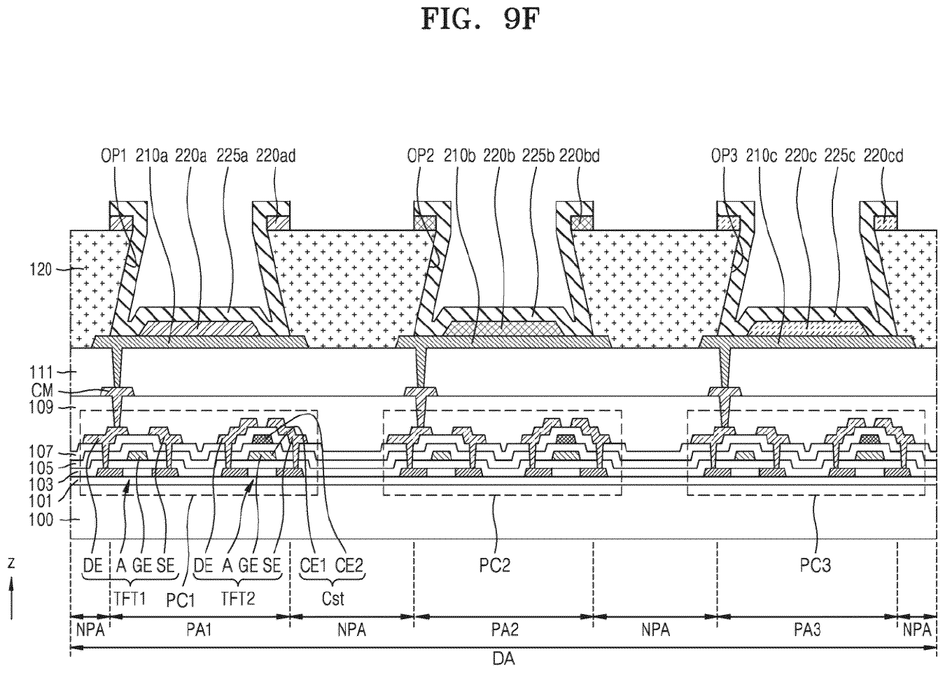

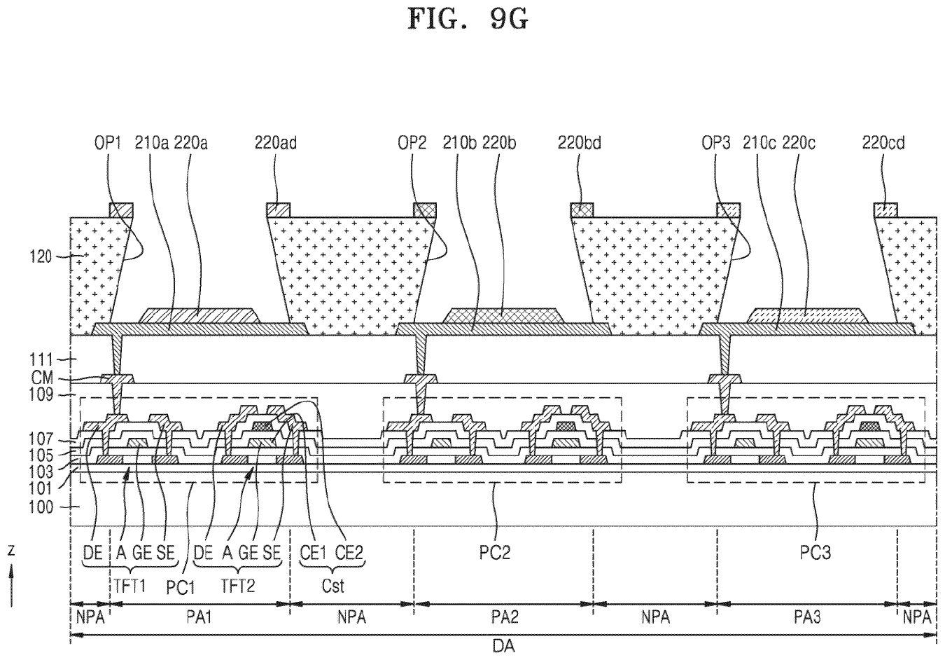

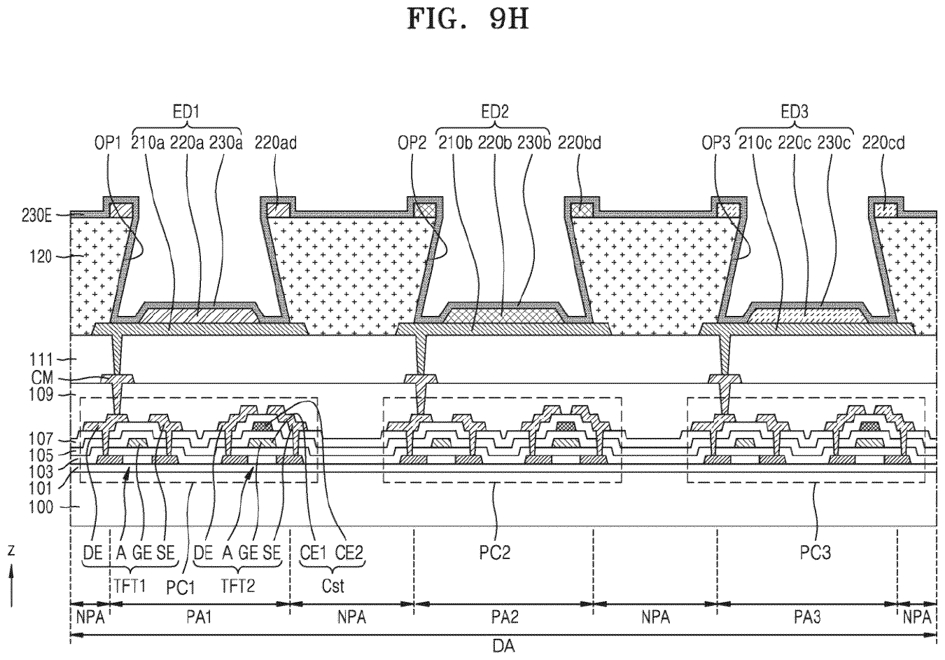

FIGS. 9A to 9H are schematic cross-sectional views showing states corresponding to a process of manufacturing a display apparatus according to one or more embodiments of the present disclosure. FIGS. 7A to 7C and FIGS. 9A to 9H show each step (e.g., task or act) of the manufacturing process in a cross-section corresponding to the cross-section of the display apparatus 1 described with reference to FIG. 6, according to one or more embodiments of the present disclosure.

Referring to FIG. 9A, the first intermediate layer 220a arranged on the first pixel electrode 210a in the first opening OP1 of the pixel-defining layer 120, a first temporary intermediate layer 220ap1 arranged on each of the second pixel electrode 210b in the second opening OP2 of the pixel-defining layer 120 and the third pixel electrode 210c in the third opening OP3 of the pixel-defining layer 120, and a first preliminary dummy intermediate layer 220ap2 arranged on the upper surface of the pixel-defining layer 120 may be formed. Because the forming of the first intermediate layer 220a, the first temporary intermediate layer 220ap1, and the first preliminary dummy intermediate layer 220ap2 is substantially the same as the description made with reference to FIG. 8A, repeated description may be omitted.

Next, a first sacrificial layer 2251 may be formed to cover the upper surface of the first intermediate layer 220a, the lateral surface defining the first opening OP1 of the pixel-defining layer 120, and the upper surface of the first preliminary dummy intermediate layer 220ap2.

In one or more embodiments, the first sacrificial layer 2251 may be formed to cover each of the lateral surface defining the first opening OP1, the lateral surface defining the second opening OP2, and the lateral surface defining the third opening OP3 of the pixel-defining layer 120. As an example, the first sacrificial layer 2251 may be arranged along each of the profile of the lateral surface defining the first opening OP1, the profile of the lateral surface defining the second opening OP2, and the profile of the lateral surface defining the third opening OP3 of the pixel-defining layer 120. As an example, the first sacrificial layer 2251 may be in contact with each of the lateral surface defining the first opening OP1, the lateral surface defining the second opening OP2, and the lateral surface defining the third opening OP3 of the pixel-defining layer 120. As an example, the first sacrificial layer 2251 may be formed to be arranged along the lateral surface of the pixel-defining layer 120 of the reverse taper shape by performing a process in which an incident angle of particles may be adjusted, such as a damage free sputter (DFS) process, an oblique angle deposition (OAD) process, and/or the like.

In one or more embodiments, the first sacrificial layer 2251 may be an inorganic layer including an inorganic material such as silicon nitride, silicon oxynitride, and/or silicon oxide. In one or more embodiments, the first sacrificial layer 2251 may be a conductive layer including a conductive material such as aluminum (Al), aluminum oxide (AlOₓ) indium tin oxide (ITO), indium zinc oxide (IZO), zinc oxide (ZnO), indium oxide (In₂O₃), indium gallium oxide (IGO), and/or aluminum zinc oxide (AZO).

The thickness of the first sacrificial layer 2251 may be formed greater than (e.g., may be thicker than) the thickness of the first opposite electrode 230a (see FIG. 6). Because the thickness of the first sacrificial layer 2251 is formed relatively greater, a damage to the first intermediate layer 220a arranged under the first sacrificial layer 2251 may be prevented or reduced during the subsequent process.

Next, a first photoresist pattern PR11 overlapping the first opening OP1 of the pixel-defining layer 120 may be formed on the first sacrificial layer 2251. The first photoresist pattern PR11 may overlap the first pixel electrode 210a and the first intermediate layer 220a. The first photoresist pattern PR11 may overlap a portion of the first preliminary dummy intermediate layer 220ap2 and a portion of the first sacrificial layer 2251.

Referring to FIG. 9A and FIG. 9B, by using the first photoresist pattern PR11 as a mask, the first dummy intermediate layer 220ad may be formed by removing the remaining portion of the first preliminary dummy intermediate layer 220ap2 that does not overlap the first photoresist pattern PR11, and a first sacrificial pattern 225a covering the upper surface of the first intermediate layer 220a, the lateral surface defining the first opening OP1 of the pixel-defining layer 120, and the upper surface of the first dummy intermediate layer 220ad may be formed by removing the remaining portion of the first sacrificial layer 2251. In such embodiments, the first temporary intermediate layer 220ap1 may be also removed together using the first photoresist pattern PR11 as a mask. The process of removing a portion of the first preliminary dummy intermediate layer 220ap2 and a portion of the first sacrificial layer 2251 using the first photoresist pattern PR11 may be, for example, a wet etching process or a dry etching process.

Referring to FIG. 9C, the second intermediate layer 220b arranged on the second pixel electrode 210b in the second opening OP2 of the pixel-defining layer 120, a second temporary intermediate layer 220bp1 arranged on each of the first sacrificial pattern 225a in the first opening OP1 of the pixel-defining layer 120 and the third pixel electrode 210c in the third opening OP3 of the pixel-defining layer 120, and a second preliminary dummy intermediate layer 220bp2 arranged on the upper surface of the pixel-defining layer 120 may be formed. Because the forming of the second intermediate layer 220b, the second temporary intermediate layer 220bp1, and the second preliminary dummy intermediate layer 220bp2 is substantially the same as the description made with reference to FIG. 8D, repeated description may be omitted.

Next, a second sacrificial layer 2252 may be formed to cover the upper surface of the second intermediate layer 220b, the lateral surface defining the second opening OP2 of the pixel-defining layer 120, and the upper surface of the second preliminary dummy intermediate layer 220bp2.

In one or more embodiments, the second sacrificial layer 2252 may be formed to cover each of the lateral surface defining the first opening OP1, the lateral surface defining the second opening OP2, and the lateral surface defining the third opening OP3 of the pixel-defining layer 120. Because the description of forming of the second sacrificial layer 2252 is substantially the same as or similar to the forming of the first sacrificial layer 2251 described with reference to FIG. 9A, a detailed description thereof may be omitted.

Next, a second photoresist pattern PR12 overlapping the second opening OP2 of the pixel-defining layer 120 may be formed on the second sacrificial layer 2252. The second photoresist pattern PR12 may overlap the second pixel electrode 210b and the second intermediate layer 220b. The second photoresist pattern PR12 may overlap a portion of the second preliminary dummy intermediate layer 220bp2 and a portion of the second sacrificial layer 2252.

Referring to FIG. 9C and FIG. 9D, by using the second photoresist pattern PR12 as a mask, the second dummy intermediate layer 220bd may be formed by removing the remaining portion of the second preliminary dummy intermediate layer 220bp2 that does not overlap the second photoresist pattern PR12, and a second sacrificial pattern 225b covering the upper surface of the second intermediate layer 220b, the lateral surface defining the second opening OP2 of the pixel-defining layer 120, and the upper surface of the second dummy intermediate layer 220bd may be formed by removing the remaining portion of the second sacrificial layer 2252. In such embodiments, the second temporary intermediate layer 220bp1 may be also removed together using the second photoresist pattern PR12 as a mask.

Referring to FIG. 9E, the third intermediate layer 220c arranged on the third pixel electrode 210c in the third opening OP3 of the pixel-defining layer 120, the third temporary intermediate layer 220cp1 arranged on each of the first sacrificial pattern 225a in the first opening OP1 of the pixel-defining layer 120 and the second sacrificial 225b in the second opening OP2 of the pixel-defining layer 120, and a third preliminary dummy intermediate layer 220cp2 arranged on the upper surface of the pixel-defining layer 120 may be formed. Because the forming of the third intermediate layer 220c, the third temporary intermediate layer 220cp1, and the third preliminary dummy intermediate layer 220cp2 is substantially the same as the description made with reference to FIG. 8F, repeated description may be omitted.

Next, a third sacrificial layer 2253 may be formed to cover the upper surface of the third intermediate layer 220c, the lateral surface defining the third opening OP3 of the pixel-defining layer 120, and the upper surface of the third preliminary dummy intermediate layer 220cp2.

In one or more embodiments, the third sacrificial layer 2253 may be formed to cover each of the lateral surface defining the first opening OP1, the lateral surface defining the second opening OP2, and the lateral surface defining the third opening OP3 of the pixel-defining layer 120. Because the description of forming of the third sacrificial layer 2253 is substantially the same as or similar to the forming of the first sacrificial layer 2251 described with reference to FIG. 9A, a detailed description thereof may be omitted.

Next, the third photoresist pattern PR13 overlapping the third opening OP3 of the pixel-defining layer 120 may be formed on the third sacrificial layer 2253. The third photoresist pattern PR13 may overlap the third pixel electrode 210c and the third intermediate layer 220c. The third photoresist pattern PR13 may overlap a portion of the third preliminary dummy intermediate layer 220cp2 and a portion of the third sacrificial layer 2253.

Referring to FIG. 9E and FIG. 9F, by using the third photoresist pattern PR13 as a mask, the third dummy intermediate layer 220cd may be formed by removing the remaining portion of the third preliminary dummy intermediate layer 220cp2 that does not overlap the third photoresist pattern PR13, and a third sacrificial pattern 225c covering the upper surface of the third intermediate layer 220c, the lateral surface defining the third opening OP3 of the pixel-defining layer 120, and the upper surface of the third dummy intermediate layer 220cd may be formed by removing the remaining portion of the third sacrificial layer 2253. In such embodiments, the third temporary intermediate layer 220cp1 may be also removed together using the third photoresist pattern PR13 as a mask.

Referring to FIG. 9G, the first sacrificial layer 225a, the second sacrificial layer 225b, and the third sacrificial layer 225c may be selectively removed. A process of removing the first sacrificial layer 225a, the second sacrificial layer 225b, and the third sacrificial layer 225c may be, for example, a wet etching process.

Referring to FIG. 9H, the opposite electrode 230E integrally provided on the first intermediate layer 220a, the second intermediate layer 220b, and the third intermediate layer 220c, and the pixel-defining layer 120 may be formed. For example, the first opposite electrode 230a of the first light-emitting element ED1, the second opposite electrode 230b of the second light-emitting element ED2, and the third opposite electrode 230c of the third light-emitting element ED3 may be one opposite electrode 230E electrically connected to each other.

The opposite electrode 230E may overlap the first intermediate layer 220a, the second intermediate layer 220b, and the third intermediate layer 220c and overlap the pixel-defining layer 120. As an example, the opposite electrode 230E may overlap the pixel-defining layer 120 and overlap the first to third openings OP1, OP2, and OP3 of the pixel-defining layer 120.

The opposite electrode 230E may be formed to cover at least a portion of the lateral surface defining the first opening OP1 of the pixel-defining layer 120, at least a portion of the lateral surface defining the second opening OP2, and at least a portion of the lateral surface defining the third opening OP3. The opposite electrode 230E may be formed to be in contact with at least a portion of the lateral surface defining the first opening OP1 of the pixel-defining layer 120, at least a portion of the lateral surface defining the second opening OP2, and at least a portion of the lateral surface defining the third opening OP3. The opposite electrode 230E may be (substantially) continuously formed to overlap (or cover) the upper surface and lateral surface of each of the first intermediate layer 220a, the second intermediate layer 220b, the third intermediate layer 220c, and the upper surface and lateral surface of the pixel-defining layer 120. As an example, the opposite electrode 230E may be formed to be arranged along the lateral surface of the pixel-defining layer 120 of the reverse taper shape by performing a process in which an incident angle of particles may be adjusted, such as a damage free sputter (DFS) process, an oblique angle deposition (OAD) process, and/or the like.

The opposite electrode 230E may be formed to cover the inner surface, the upper surface, and the outer surface of the first dummy intermediate layer 220ad, cover the inner surface, the upper surface, and the outer surface of the second dummy intermediate layer 220bd, and cover the inner surface, the upper surface, and the outer surface of the third dummy intermediate layer 220cd.

The display apparatus according to the embodiment may be applied to various electronic apparatuses. An electronic apparatus according to an embodiment of the present disclosure may include the display apparatus (e.g., the display apparatus of FIG. 1A) described above, and may further include modules or apparatuses having additional functions in addition to the display apparatus.

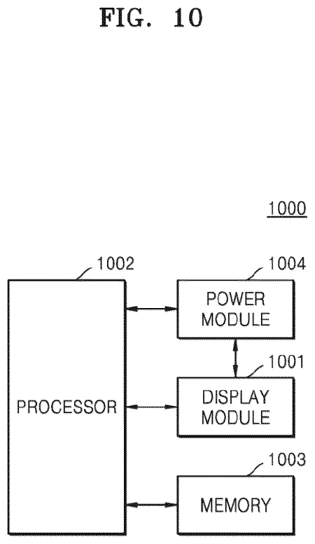

FIG. 10 is a block diagram of an electronic apparatus according to an embodiment.

Referring to FIG. 10, an electronic apparatus 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic apparatus 1000.

At least one of the components of the electronic apparatus 1000 described above may be included in the display apparatus according to the embodiments described above. In addition, a part among the individual modules functionally included in one module may be included in the display apparatus, and another part may be provided separately from the display apparatus. For example, the display apparatus may include the display module 1001, and the processor 1002, the memory 1003, and the power module 1004 may be provided in the form of other apparatuses within the electronic apparatus 1000 except for the display apparatus.

In an embodiment, the display module 1001 included in the display apparatus may drive based on the image data signal and the input control signal received from the processor 1002.

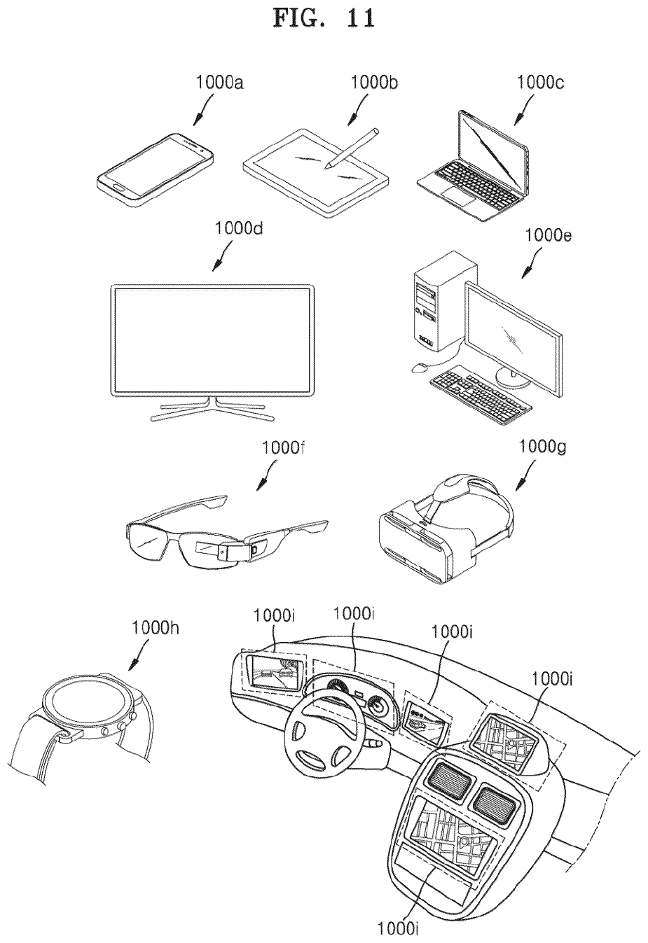

FIG. 11 is schematic diagrams of electronic apparatuses according to various embodiments.

Referring to FIG. 11, various electronic apparatuses to which display apparatuses according to embodiments are applied may include not only image display electronic apparatuses such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

Because the display apparatus according to one or more embodiments includes the pixel-defining layer having the reverse taper shape, manufacturing costs and/or manufacturing time of the display apparatus may be reduced. That is, according to one or more embodiments, the display apparatus is equipped with a pixel-defining layer designed with a reverse taper configuration to provide a reduction in both the manufacturing costs and the production time associated with the display apparatus. However, this is an example, and the scope of the disclosure is not limited thereto.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value.

The light emitting device, electronic apparatus, a device for manufacturing thereof, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be 1 implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display apparatus comprising:
a first pixel electrode and a second pixel electrode arranged apart from each other;
a pixel-defining layer on the first pixel electrode and the second pixel electrode, having a first opening exposing a portion of the first pixel electrode and a second opening exposing a portion of the second pixel electrode, and having a reverse taper shape in a cross-sectional view;
a first intermediate layer and a second intermediate layer in the first opening and the second opening of the pixel-defining layer, respectively;
a first opposite electrode on the first intermediate layer in the first opening of the pixel-defining layer and a second opposite electrode on the second intermediate layer in the second opening of the pixel-defining layer;
a first dummy pattern and a second dummy pattern each on an upper surface of the pixel-defining layer, wherein the first dummy pattern comprises substantially the same material as the first intermediate layer, and the second dummy pattern comprises substantially the same material as the second intermediate layer;
a first auxiliary electrode pattern covering an upper surface of the first opposite electrode, a lateral surface of the pixel-defining layer that defines the first opening, and an upper surface of the first dummy pattern;
a second auxiliary electrode pattern covering an upper surface of the second opposite electrode, a lateral surface of the pixel-defining layer that defines the second opening, and an upper surface of the second dummy pattern; and
an auxiliary electrode layer on the first auxiliary electrode pattern, the second auxiliary electrode pattern, and the pixel-defining layer.

2. The display apparatus of claim 1, wherein the auxiliary electrode layer overlaps an entirety of the first auxiliary electrode pattern, an entirety of the second auxiliary electrode pattern, and an entirety of the pixel-defining layer.

3. The display apparatus of claim 1, wherein a thickness of the first auxiliary electrode pattern is greater than a thickness of the first opposite electrode.

4. The display apparatus of claim 1, wherein the first auxiliary electrode pattern is apart from the second auxiliary electrode pattern.

5. The display apparatus of claim 1, wherein each of the first auxiliary electrode pattern and the second auxiliary electrode pattern has an island pattern shape in a plan view.

6. The display apparatus of claim 1, wherein the first auxiliary electrode pattern covers an inner surface of the first dummy pattern, and
the second auxiliary electrode pattern covers an inner surface of the second dummy pattern.

7. The display apparatus of claim 6, wherein the auxiliary electrode layer covers an outer surface of the first dummy pattern and an outer surface of the second dummy pattern.

8. The display apparatus of claim 1, wherein the first dummy pattern is apart from the second dummy pattern, wherein the first dummy pattern comprises:
a first dummy intermediate layer comprising substantially the same material as the first intermediate layer; and
a first dummy opposite electrode comprising substantially the same material as the first opposite electrode, and
wherein the second dummy pattern comprises:
a second dummy intermediate layer comprising substantially the same material as the second intermediate layer; and
a second dummy opposite electrode comprising substantially the same material as the second opposite electrode.

9. The display apparatus of claim 1, wherein each of the first auxiliary electrode pattern and the second auxiliary electrode pattern comprises a light-transmissive conductive material.

10. The display apparatus of claim 1, wherein the pixel-defining layer comprises a negative type photosensitive organic material.

11. A display apparatus comprising:
a first pixel electrode and a second pixel electrode arranged apart from each other;
a pixel-defining layer on the first pixel electrode and the second pixel electrode, having a first opening exposing a portion of the first pixel electrode and a second opening exposing a portion of the second pixel electrode, and having a reverse taper shape in a cross-sectional view;
a first intermediate layer and a second intermediate layer in the first opening and the second opening of the pixel-defining layer, respectively;
an opposite electrode covering the first intermediate layer, the second intermediate layer, an upper surface of the pixel-defining layer, at least a portion of a lateral surface of the pixel-defining layer that defines the first opening, and at least a portion of a lateral surface of the pixel-defining layer that defines the second opening; and
a first dummy pattern and a second dummy pattern each on an upper surface of the pixel-defining layer, wherein the first dummy pattern comprises substantially the same material as the first intermediate layer, and the second dummy pattern comprises substantially the same material as the second intermediate layer.

12. The display apparatus of claim 11, wherein the opposite electrode overlaps an entirety of an upper surface of the pixel-defining layer.

13. The display apparatus of claim 11, wherein the first dummy pattern is apart from the second dummy pattern.

14. The display apparatus of claim 11, wherein the opposite electrode is in contact with the first dummy pattern and the second dummy pattern.

15. The display apparatus of claim 11, wherein the pixel-defining layer comprises a negative type photosensitive organic material.

16. An electronic apparatus comprising:
a first pixel electrode and a second pixel electrode arranged apart from each other;
a pixel-defining layer on the first pixel electrode and the second pixel electrode, having a first opening exposing a portion of the first pixel electrode and a second opening exposing a portion of the second pixel electrode, and having a reverse taper shape in a cross-sectional view;
a first intermediate layer and a second intermediate layer in the first opening and the second opening of the pixel-defining layer, respectively;
a first opposite electrode on the first intermediate layer in the first opening of the pixel-defining layer, and a second opposite electrode on the second intermediate layer in the second opening of the pixel-defining layer; and
a first dummy pattern and a second dummy pattern each on an upper surface of the pixel-defining layer, wherein the first dummy pattern comprises substantially the same material as the first intermediate layer, and the second dummy pattern comprises substantially the same material as the second intermediate layer,
wherein the first dummy pattern is apart from the second dummy pattern, and
the first opposite electrode is electrically connected to the second opposite electrode.

17. The electronic apparatus of claim 16, further comprising:
a first auxiliary electrode pattern covering an upper surface of the first opposite electrode, a lateral surface of the pixel-defining layer that defines the first opening, and an upper surface of the first dummy pattern;
a second auxiliary electrode pattern covering an upper surface of the second opposite electrode, a lateral surface of the pixel-defining layer that defines the second opening, and an upper surface of the second dummy pattern; and
an auxiliary electrode layer on the first auxiliary electrode pattern and the second auxiliary electrode pattern,
wherein the auxiliary electrode layer electrically connects the first auxiliary electrode pattern to the second auxiliary electrode pattern.

18. The electronic apparatus of claim 16, wherein the first opposite electrode and the second opposite electrode are integrally provided to overlap an entire upper surface of the pixel-defining layer.

19. The electronic apparatus of claim 16, wherein the pixel-defining layer comprises a negative type photosensitive organic material.

20. The electronic apparatus of claim 16, further comprising:
a display module;
a processor;
a power module; and
a memory,
wherein the display apparatus includes one of the display module, the processor, the power module, or the memory.
